(19) United States
(12) Patent Application Publication
(10) Pub. No.: US 2024/0324325 A1
(43) Pub. Date: Sep. 26, 2024

(54) Display Panel and Display Apparatus

(71) Applicant: Samsung Display Co., Ltd., Yongin-Si, Gyeonggi-Do (KR)

(72) Inventors: Byunggoo JUNG, Yongin-si, Gyeonggi-do (KR); Sunil CHOI, Yongin-si, Gyeonggi-do (KR); Sungjun KIM, Yongin-si, Gyeonggi-do (KR); Wangwoo LEE, Yongin-si, Gyeonggi-do (KR)

(21) Appl. No.: 18/611,705

(22) Filed: Mar. 21, 2024

(30) Foreign Application Priority Data
Mar. 24, 2023 (KR) 10-2023-0039212
Jun. 12, 2023 (KR) 10-2023-0075059

(51) Int. Cl. H10K 59/124

(52) U.S. Cl. CPC H10K 59/124

(57) ABSTRACT

A display panel includes a substrate including a first area, a second area surrounding the first area, and a third area between the first area and the second area, a first pixel circuit arranged in the third area and including a first transistor, a storage capacitor, and a second transistor, a first organic insulating layer disposed on the first transistor and the second transistor, a second organic insulating layer disposed on the first organic insulating layer, a first light-emitting diode arranged in the first area and electrically connected to the first pixel circuit, the first light-emitting diode including a first electrode disposed on the second organic insulating layer, and a conductive pattern layer disposed on the first organic insulating layer in a fourth area that is a boundary between the first area and the second area, the conductive pattern layer including a plurality of holes.

### CROSS-REFERENCE TO RELATED APPLICATIONS

This application is based on and claims priority under 35 U.S.C. § 119 to Korean Patent Application No. 10-2023-0039212, filed on Mar. 24, 2023, and 10-2023-0075059, filed on Jun. 12, 2023, in the Korean Intellectual Property Office, the disclosures of which are incorporated by reference herein in their entireties.

### BACKGROUND

### 1. Field

One or more embodiments relate to a display panel and a display apparatus including the same.

### 2. Description of the Related Art

Recently, the usage of display apparatuses has diversified. Also, as display apparatuses have become thinner and lighter, the range of use thereof has expanded.

Among display apparatuses, organic light-emitting display apparatuses have the advantages of wide viewing angles, excellent contrast, and fast response times, and thus have attracted attention as next-generation display apparatuses.

In general, an organic light-emitting display apparatus includes a thin-film transistor and an organic light-emitting diode as a display element on a substrate. The organic light-emitting diode operates to emit light by itself. Such organic light-emitting display apparatuses may be used as displays for small products such as mobile phones or large products such as televisions.

### SUMMARY

One or more embodiments include a display panel, in which reliability and visibility are improved, and a display apparatus including the same. However, this is only an example and the scope of the disclosure is not limited thereby.

Additional aspects will be set forth in part in the description which follows and, in part, will be apparent from the description, or may be learned by practice of the presented embodiments of the disclosure.

According to one or more embodiments, a display panel includes a substrate including a first area, a second area at least partially surrounding the first area, and a third area between the first area and the second area, a first pixel circuit arranged in the third area and including a first transistor, a storage capacitor, and a second transistor, wherein the first transistor includes a first semiconductor layer and a first gate electrode, and a second transistor includes a second semiconductor layer and a second gate electrode, a first organic insulating layer disposed on the first transistor and the second transistor, a second organic insulating layer disposed on the first organic insulating layer, a first light-emitting diode arranged in the first area and electrically connected to the first pixel circuit, the first light-emitting diode including a first electrode disposed on the second organic insulating layer, and a conductive pattern layer disposed on the first organic insulating layer in a fourth area that is a boundary between the first area and the second area, the conductive pattern layer including a plurality of holes.

According to the present embodiment, an area occupied by the plurality of holes among an area of the conductive pattern layer a may be from about 30% to about 40%.

According to the present embodiment, an area of at least one of the plurality of holes in the conductive pattern layer may be from about 265 μm² to about 365 μm².

According to the present embodiment, each of the plurality of holes in the conductive pattern layer may have a rectangular shape.

According to the present embodiment, the each of plurality of holes in the conductive pattern layer may have a square shape.

According to the present embodiment, a length of one side of the each of the plurality of holes in the conductive pattern layer may be from about 16.3 μm to about 19.1 μm.

According to the present embodiment, each of the plurality of holes in the conductive pattern layer may have a circular shape.

According to the present embodiment, a radius of at least one of the each of the plurality of holes in the conductive pattern layer may be from about 9.2 μm to about 10.78 μm.

According to the present embodiment, the display panel may further include a third organic insulating layer disposed between the first organic insulating layer and the second organic insulating layer, and a first connection wiring disposed on the third organic insulating layer. According to the present embodiment, the display panel may further include a fourth organic insulating layer disposed between the second organic insulating layer and the third organic insulating layer, and a second connection wiring disposed on the fourth organic insulating layer.

According to the present embodiment, the first light-emitting diode may further include a first intermediate layer disposed on the first electrode and a first opposite electrode disposed on the first intermediate layer.

According to the present embodiment, the display panel may further include a second pixel circuit arranged in the second area, and a second light-emitting diode arranged in the second area and electrically connected to the second pixel circuit.

According to the present embodiment, the display panel may further include a third pixel circuit arranged in the third area, and a third light-emitting diode arranged in the third area and electrically connected to the third pixel circuit.

According to the present embodiment, the first area may include a transmission area.

According to the present embodiment, the first light-emitting diode and the transmission area may be alternately arranged in the first area.

According to one or more embodiments, a display apparatus includes a display panel including a first area, a second area at least partially surrounding the first area, and a third area between the first area and the second area, and a component disposed on a lower surface of the display panel and overlapping at least a portion of the first area, wherein the display panel further includes a first pixel circuit arranged in the third area and including a first transistor, a storage capacitor, and a second transistor, wherein the first transistor includes a first semiconductor layer and a first gate electrode, and a second transistor including a second semiconductor layer and a second gate electrode, a first organic insulating layer disposed on the first transistor and the second transistor, a second organic insulating layer disposed on the first organic insulating layer, a first light-emitting diode arranged in the first area and electrically connected to the first pixel circuit, the first light-emitting diode including a first electrode disposed on the second organic insulating layer, and a conductive pattern layer disposed on the first organic insulating layer in a fourth area that is a boundary between the first area and the second area, the conductive pattern layer including a plurality of holes.

According to the present embodiment, an area occupied by the plurality of holes among an area of the conductive pattern layer may be from about 30% to about 40%.

According to the present embodiment, an area of at least one of the plurality of holes in the conductive pattern layer may be from about 265 μm² to about 365 μm².

According to the present embodiment, each of the plurality of holes in the conductive pattern layer may have a square shape.

According to the present embodiment, a length of one side of the each of the plurality of holes in the conductive pattern layer may be from about 16.3 μm to about 19.1 μm.

### BRIEF DESCRIPTION OF THE DRAWINGS

The above and other aspects, features, and advantages of certain embodiments of the disclosure will be more apparent from the following description taken in conjunction with the accompanying drawings, in which:

FIGS. 1A and 1B are perspective views schematically illustrating a display apparatus according to an embodiment;

FIGS. 2A and 2B are cross-sectional views schematically illustrating a portion of an electronic apparatus according to an embodiment;

FIGS. 3A and 3B are plan views schematically illustrating a display panel of a display apparatus, according to an embodiment;

FIG. 4 is a partial enlarged plan view schematically illustrating a display apparatus according to an embodiment;

FIG. 5 is an equivalent circuit diagram schematically illustrating a sub-pixel circuit electrically connected to a light-emitting diode corresponding to a sub-pixel of a display apparatus, according to an embodiment;

FIG. 6 is a cross-sectional view of a portion of the display panel of the display apparatus of FIG. 3A taken along line A-A′ of FIG. 3A, according to an embodiment;

FIGS. 7A and 7B are cross-sectional views schematically illustrating a portion of a display apparatus according to an embodiment; and

FIGS. 8A and 8B are schematic plan views of a conductive pattern layer according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the present description allows for various changes and numerous embodiments, certain embodiments will be illustrated in the drawings and described in detail in the written description. Effects and features of the disclosure, and methods of achieving them will be clarified with reference to embodiments described below in detail with reference to the drawings. However, the disclosure is not limited to the following embodiments and may be embodied in various forms.

Hereinafter, embodiments will be described in detail with reference to the accompanying drawings. When describing embodiments with reference to the accompanying drawings, the same or corresponding elements are denoted by the same reference numerals.

It will be understood that although the terms “first,” “second,” etc. may be used herein to describe various elements, these elements should not be limited by these terms. These terms are only used to distinguish one element from another.

The singular forms as used herein are intended to include the plural forms as well unless the context clearly indicates otherwise.

It will be further understood that the terms “include” and/or “comprise” used herein specify the presence of stated features or elements, but do not preclude the presence or addition of one or more other features or elements.

It will be further understood that, when a layer, region, or element is referred to as being “on” another layer, region, or element, it may be directly or indirectly on the other layer, region, or element. That is, for example, intervening layers, regions, or elements may be present.

Also, sizes of elements in the drawings may be exaggerated or reduced for convenience of explanation. For example, because sizes and thicknesses of elements in the drawings are arbitrarily illustrated for convenience of explanation, the disclosure is not limited thereto.

When a certain embodiment may be implemented differently, a specific process order may be performed differently from the described order. For example, two consecutively described processes may be performed substantially at the same time or performed in an order opposite to the described order.

Throughout the disclosure, the expression “at least one of A and B” “A and/or B” indicates only A, only B, or both A and B. In this specification, the expression “at least one of A and B” indicates only A, only B, or both A and B.

It will be further understood that when layers, regions, or elements are referred to as being connected to each other, they may be directly connected to each other or indirectly connected to each other with intervening layers, regions, or elements therebetween. For example, when layers, regions, or elements are referred to as being electrically connected to each other, they may be directly electrically connected to each other or indirectly electrically connected to each other with intervening layers, regions, or elements therebetween.

The x-axis, the y-axis, and the z-axis are not limited to three axes of the rectangular coordinate system and may be interpreted in a broader sense. For example, the x-axis, the y-axis, and the z-axis may be perpendicular to one another or may represent different directions that are not perpendicular to one another.

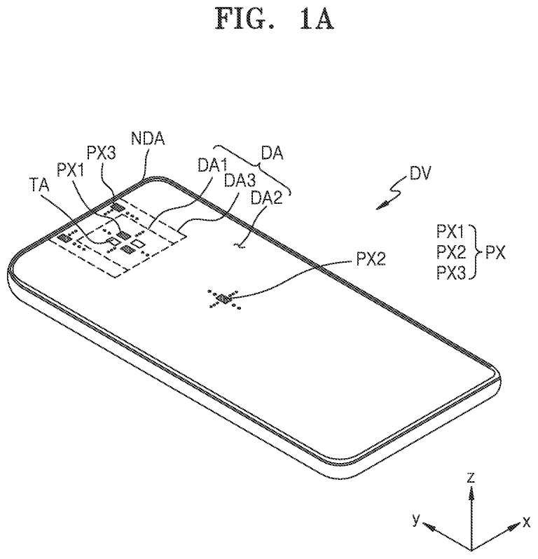

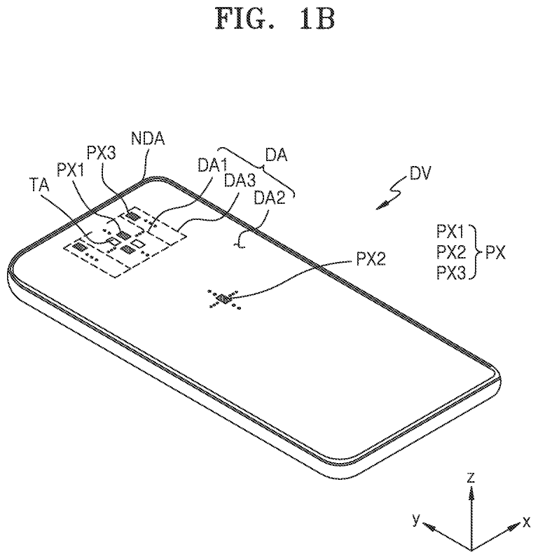

FIGS. 1A and 1B are perspective views schematically illustrating a display apparatus DV according to an embodiment.

Referring to FIGS. 1A and 1B, the display apparatus DV may display an image. The display apparatus DV may include a sub-pixel PX. The sub-pixel PX may be defined as an area in which a display element emits light. The display apparatus DV may include a plurality of sub-pixels PX. The sub-pixels PX may each emit light and may each be, for example, a red sub-pixel, a green sub-pixel, or a blue sub-pixel. In an embodiment, the display apparatus DV may include a first sub-pixel PX1, a second sub-pixel PX2, and a third sub-pixel PX3.

The display apparatus DV may include a display area DA and a non-display area NDA surrounding the display area DA. The display area DA may include a first display area DA1, a second display area DA2, and a third display area DA3. The sub-pixels PX may be disposed in the first display area DA1, the second display area DA2, and the third display area DA3, and the sub-pixels PX may not be disposed in the non-display area NDA.

The second display area DA2 may at least partially surround the first display area DA1 and the third display area DA3. In an embodiment, the second display area DA2 may partially surround the first display area DA1 and the third display area DA3. In another embodiment, the second display area DA2 may completely surround the first display area DA1 and the third display area DA3. The second display area DA2 may include the second sub-pixel PX2. the second display area DA2 may include a plurality of second sub-pixels PX2.

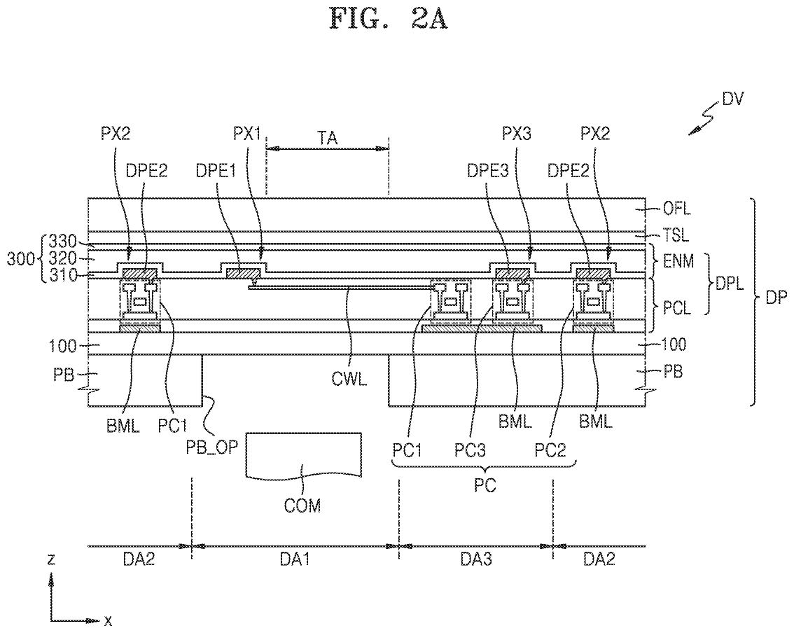

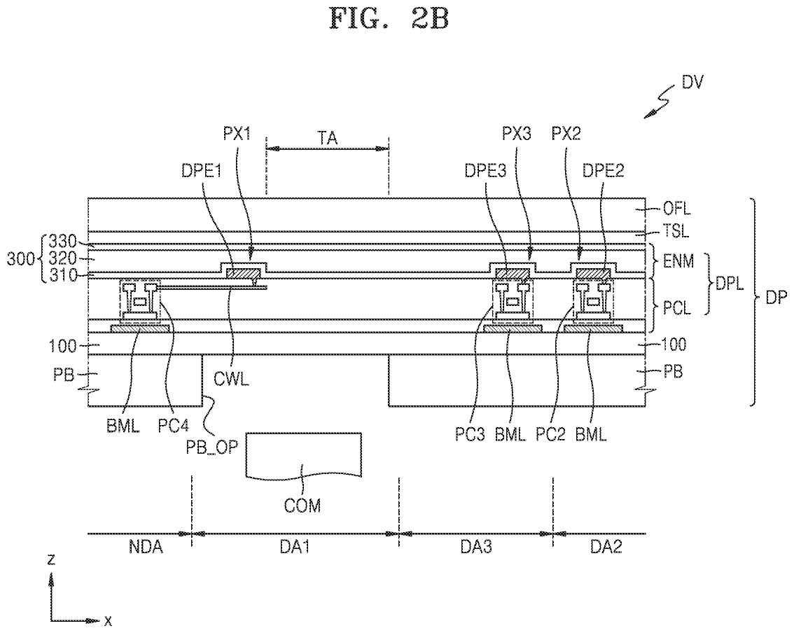

At least one of the first display area DA1 and the third display area DA3 may overlap a component. For example, as described below with reference to FIG. 2A, a component (see COM of FIG. 2A), which is an electronic element, may be disposed below the display apparatus DV to correspond to the first display area DA1. At least one of the first display area DA1 and the third display area DA3 may include a transmission area TA through which light and/or sound output from the component COM to the outside or light and/or sound traveling from the outside toward the component COM pass.

At least one of the first display area DA1 and the third display area DA3 may be an area which overlaps the component and in which the sub-pixel PX is arranged. For example, the first display area DA1 may be an area which overlaps the component and in which the sub-pixel PX is arranged. In another embodiment, the first display area DA1 and the third display area DA3 may be an area which overlaps the component and in which the sub-pixel PX is arranged. In an embodiment, the first sub-pixel PX1 may be disposed in the first display area DA1. The first display area DA1 may include a plurality of first sub-pixels PX1. The third sub-pixel PX3 may be disposed in the third display area DA3. The third display area DA3 may include a plurality of third sub-pixels PX3.

In an embodiment, an image displayed on at least one of the first display area DA1 and the third display area DA3 may have a lower resolution than an image displayed on the second display area DA2. For example, the resolution of the first display area DA1 may be approximately ½, ⅜, ⅓, ¼, 2/9, ⅛, 1/9, or 1/16 of the resolution of the second display area DA2. For example, the resolution of the second display area DA2 may be about 400 ppi or more, and the resolution of the first display area DA1 may be about 200 ppi or about 100 ppi. In another embodiment, the resolution of at least one of the first display area DA1 and the third display area DA3 may be equal to the resolution of the second display area DA2.

At least one of the first display area DA1 and the third display area DA3 may overlap the component and may include the transmission area TA. When the sub-pixel PX is not in the transmission area TA, the number of sub-pixels PX that may be arranged per unit area in at least one of the first display area DA1 and the third display area DA3 may be less than the number of sub-pixels PX arranged per unit area in the second display area DA2. For example, the number of first sub-pixels PX1 that may be arranged per unit area in the first display area DA1 may be less than the number of second sub-pixels PX2 arranged per unit area in the second display area DA2.

At least one of the first display area DA1 and the third display area DA3 may have higher light transmittance or sound transmittance than the second display area DA2. For example, the transmittance of the display apparatus DV in at least one of the first display area DA1 and the third display area DA3 may be about 10% or more, specifically about 40% or more, 25% or more, 50% or more, 85% or more, or 90% or more.

The display apparatus DV may include at least one first display area DA1. For example, the display apparatus DV may include one first display area DA1 or may include a plurality of first display areas DA1.

The third display area DA3 may be disposed adjacent to the first display area DA1. The third display area DA3 may be disposed on one side of the first display area DA1. For example, the first display area DA1 and the third display area DA3 may be arranged side-by-side in a first direction (e.g., the x direction or the −x direction). As another example, the first display area DA1 and the third display area DA3 may be arranged side-by-side in a second direction (e.g., the y direction or the −y direction). In an embodiment, the third display area DA3 may be disposed on both sides of the first display area DA1. In some embodiments, the third display area DA3 may be omitted.

FIGS. 1A and 1B illustrate that the first display area DA1 and the third display area DA3 are disposed in the upper center of the display apparatus DV, but in another embodiment, the first display area DA1 and the third display area DA3 may be disposed in the lower portion, right side, or left side of the display apparatus DV.

In an embodiment, at least one of the first display area DA1 and the third display area DA3 may have various shapes, such as a polygonal shape (e.g., a circular shape, an elliptical shape, or a rectangular shape), a star shape, or a diamond shape, in a plan view (e.g., an x-y plane). In an embodiment, FIGS. 1A and 1B illustrate that the first display area DA1 and the third display area DA3 each have a rectangular shape.

The non-display area NDA may surround at least a portion of the second display area DA2. In an embodiment, the non-display area NDA may completely surround the second display area DA2. In an embodiment, the non-display area NDA may completely surround the first display area DA1, the second display area DA2, and the third display area DA3.

The display apparatus DV of FIGS. 1A and 1B may be used in the following electronic apparatuses. For example, the display apparatus DV according to an embodiment may be used in portable electronic apparatuses, such as mobile phones, smartphones, tablet personal computers (PCs), mobile communication terminals, electronic organizers, e-books, portable multimedia players (PMPs), navigation systems, and ultra mobile PCs (UMPCs). The display apparatus DV according to an embodiment may also be used in wearable devices, such as smart watches, watch phones, glasses-type displays, and head mounted displays (HMDs). In addition, the display apparatus DV according to an embodiment may be used in dashboards of automobiles, center information displays (CIDs) on the center fascia or dashboards of automobiles, room mirror displays replacing side mirrors of automobiles, and displays on the rear sides of front seats to serve as entertainment devices for backseat passengers of automobiles.

FIGS. 2A and 2B are cross-sectional views schematically illustrating a portion of an electronic apparatus according to an embodiment.

Referring to FIGS. 2A and 2B, the electronic apparatus may include a display apparatus DV and a component COM overlapping the display apparatus DV. In addition, the electronic apparatus may further include a housing (not shown) accommodating the display apparatus DV and a cover window (not shown) disposed above the display apparatus DV and protecting the display apparatus DV.

The display apparatus DV may include a display panel DP. In addition, the display apparatus DV may further include an input sensor (not shown) and a driving circuit (not shown). The input sensor (not shown) may be configured to sense an external input. The display panel DP may include a substrate 100, a display layer DPL, a touch screen layer TSL, an optical functional layer OFL, and a panel protection member PB. The display layer DISL, the touch screen layer TSL, and the optical functional layer OFL may be disposed over the substrate 100, and the panel protection member PB may be disposed under the substrate 100.

The component COM may be an electronic element that uses light or sound. Examples of the electronic element may include a proximity sensor configured to measure distance, a sensor configured to recognize a part of a user's body (e.g., a fingerprint, an iris, a face, etc.), a small lamp configured to output light, or an image sensor (e.g., a camera) configured to capture an image. The electronic element that uses light may use light of various wavelength bands, such as visible light, infrared light, or ultraviolet light. The electronic element that uses sound may use ultrasonic waves or sound of other frequency bands. In some embodiments, the component COM may include sub-components, such as a light emitter and a light receiver. The light emitter and the light receiver may have an integrated structure, or a pair of a light emitter and a light receiver may constitute one component COM in a physically separated structure.

The display panel DP may include a first display area DA1, a second display area DA2, and a third display area DA3. In other words, the first display area DA1, the second display area DA2, and the third display area DA3 may be defined in the substrate 100 and may include multilayer layers disposed on the substrate 100. Hereinafter, a case where the substrate 100 includes the first display area DA1, the second display area DA2, and the third display area DA3 will be described in detail.

The display layer DPL may include a pixel circuit layer PCL including a sub-pixel circuit PC, a display element layer including a display element that is a light-emitting device, and an encapsulation member ENM such as a thin-film encapsulation layer 300 or an encapsulation substrate (not shown). An insulating layer may be disposed between the substrate 100 and the display layer DPL and may be a portion of the display layer DPL. The display element may include a light-emitting diode. In an embodiment, the display element may be an organic light-emitting diode. Hereinafter, a case where the light-emitting diode includes the organic light-emitting diode has been described, but the disclosure is not limited thereto. In another embodiment, the display element according to the disclosure may be a light-emitting diode including an inorganic material or a quantum dot light-emitting diode including quantum dots. For example, an intermediate layer of the display element may include an organic material, an inorganic material, or quantum dots, may include an organic material and quantum dots, or may include an inorganic material and quantum dots.

The substrate 100 may include an insulating material such as glass, quartz, or polymer resin. The substrate 100 may be a rigid substrate or a bendable, foldable, rollable, or flexible substrate.

The pixel circuit layer PCL may be disposed on the substrate 100. The pixel circuit layer PCL may include the sub-pixel circuit PC, a connection wiring CWL, and an insulating layer. The sub-pixel circuit PC may include a first sub-pixel circuit PC1, a second sub-pixel circuit PC2, and a third sub-pixel circuit PC3. The first sub-pixel circuit PC1 and the third sub-pixel circuit PC3 may be disposed in the third display area DA3. The second sub-pixel circuit PC2 may be disposed in the second display area DA2. The sub-pixel circuit PC may not be in the first display area DA1.

In an embodiment, a second display element DPE2 and a second sub-pixel circuit PC2 connected thereto may be disposed in the second display area DA2 of the substrate 100. The second sub-pixel circuit PC2 may include at least one thin-film transistor and may be configured to control the operation of the second display element DPE2. The second sub-pixel PX2 may include the second display element DPE2 which emits light.

In an embodiment, a first display element DPE1 may be disposed in the first display area DA1 of the substrate 100 and may constitute the first sub-pixel PX1. In an embodiment, as illustrated in FIG. 2A, the first sub-pixel circuit PC1 configured to drive the first display element DPE1 may not be disposed in the first display area DA1, but may be disposed in the third display area DA3 which is disposed between the first display area DA1 and the second display area DA2. In another embodiment, as illustrated in FIG. 2B, the first sub-pixel circuit PC1 configured to drive the first display element DPE1 may not be disposed in the third display area DA3, but may be disposed in the non-display area NDA. That is, the first sub-pixel circuit PC1 may be disposed not to overlap the first display element DPE1.

The first sub-pixel circuit PC1 may include at least one thin-film transistor, and may be electrically connected to the first display element DPE1 through the connection wiring CWL. The connection wiring CWL may include a transparent conductive material. The first sub-pixel circuit PC1 may be configured to control the operation of the first display element DPE1. The first sub-pixel PX1 may include the first display element DPE1 which emits light.

An area of the first display area DA1 in which the first sub-pixel PX1 is not arranged may be defined as a transmission area TA. The transmission area TA may be an area through which a signal and/or light emitted from the component COM arranged to correspond to the first display area DA1 or a signal and/or light incident on the component COM is transmitted.

The connection wiring CWL that connects the first sub-pixel circuit PC1 to the first display element DPE1 may be in the transmission area TA. Because the connection wiring CWL may include a transparent conductive material having high transmittance, the transmittance of the transmission area TA may be secured even when the connection wiring CWL is disposed in the transmission area TA.

In an embodiment, the third sub-pixel PX3 may be implemented by arranging a third display element DPE3 and the third sub-pixel circuit PC3 connected thereto in the third display area DA3 of the substrate 100. The first sub-pixel circuit PC1 and the third sub-pixel circuit PC3 in the third display area DA3 may be alternately arranged adjacent to each other.

The display element layer may be covered with the thin-film encapsulation layer 300, as illustrated in FIGS. 2A and 2B, or may be covered with the encapsulation substrate. In an embodiment, the thin-film encapsulation layer 300 may include at least one inorganic encapsulation layer and at least one organic encapsulation layer. For example, the thin-film encapsulation layer 300 may include a first inorganic encapsulation layer 310, a second inorganic encapsulation layer 330, and an organic encapsulation layer 320 disposed therebetween.

The touch screen layer TSL may be configured to obtain coordinate information according to an external input, for example, a touch event. The touch screen layer TSL may include touch electrodes and touch lines connected to the touch electrodes. The touch screen layer TSL may be configured to sense an external input by using a self-capacitance method or a mutual capacitance method.

The touch screen layer TSL may be disposed on the thin-film encapsulation layer 300. Alternatively, the touch screen layer TSL may be separately formed on a touch substrate and then coupled to the thin-film encapsulation layer 300 through an adhesive layer such as an optically clear adhesive (OCA). In an embodiment, the touch screen layer TSL may be formed directly on the thin-film encapsulation layer 300. In this case, the adhesive layer may not be disposed between the touch screen layer TSL and the thin-film encapsulation layer 300.

The optical functional layer OFL may include an anti-reflection layer. The anti-reflection layer may reduce the reflectance of light (external light) incident from the outside toward the display apparatus DV. In an embodiment, the optical functional layer OFL may be a polarizing film. In another embodiment, the optical functional layer OFL may have an opening (not shown) corresponding to the transmission area TA. Accordingly, the transmittance of the transmission area TA may be remarkably improved. The opening may be filled with a transparent material such as optically clear resin (OCR). In another embodiment, the optical functional layer OFL may include a filter plate including a black matrix and color filters.

The panel protection member PB may be disposed under the substrate 100. The panel protection member PB may support and protect the substrate 100. The panel protection member PB may include an opening PB_OP overlapping the first display area DA1. In another embodiment, the opening PB_OP of the panel protection member PB may overlap the first display area DA1 and the third display area DA3. In an embodiment, the panel protection member PB may include polyethylene terephthalate (PET) or polyimide.

In an embodiment, the area of the opening PB_OP of the panel protection member PB may be greater than the area where the component COM is arranged. Although FIGS. 2A and 2B illustrate that the component COM is spaced apart from one side of the display panel DP, at least a portion of the component COM may be inserted into the opening PB_OP of the panel protection member PB.

The cover window (not shown) may be disposed above the display apparatus DV. The cover window may protect the display apparatus DV, for example, the display panel DP. The cover window may include at least one of glass, sapphire, or plastic. The cover window may be, for example, ultra-thin glass (UTG) or colorless polyimide (CPI).

The component COM may be disposed under the display apparatus DV. In an embodiment, the component COM may be disposed opposite to the cover window (not shown) with the display panel DP disposed therebetween. In an embodiment, the component COM may overlap the first display area DA1. In an embodiment, the component COM may overlap the first display area DA1 and the third display area DA3.

One or more components COM may be arranged. The components COM may have different functions. For example, the components COM may include at least two of a camera (imaging device), a solar cell, a flash, a proximity sensor, an illumination sensor, and an iris sensor.

In some embodiments, as illustrated in FIGS. 2A and 2B, a bottom metal layer BML may be disposed under the sub-pixel circuit PC. The bottom metal layer BML may overlap the sub-pixel circuit PC in order to protect the sub-pixel circuit PC. In an embodiment, the bottom metal layer BML may be disposed to overlap the first and/or third sub-pixel circuits PC1 and PC3 disposed between the substrate 100 corresponding to the third display area DA3 and the first and/or third sub-pixel circuits PC1 and PC3. The bottom metal layer BML may block external light from reaching the first and/or third sub-pixel circuits PC1 and PC3. In addition, the bottom metal layer BML may be disposed under the second sub-pixel circuit PC2 of the second display area DA2. The bottom metal layer BML disposed below the second sub-pixel circuit PC2 may be spaced apart from the bottom metal layer BML disposed below the first and/or third sub-pixel circuits PC1 and PC3. In another embodiment, the bottom metal layer BML may be formed to correspond to the entire display area DA and may include a hole corresponding to the first display area DA1. In another embodiment, the bottom metal layer BML may be omitted.

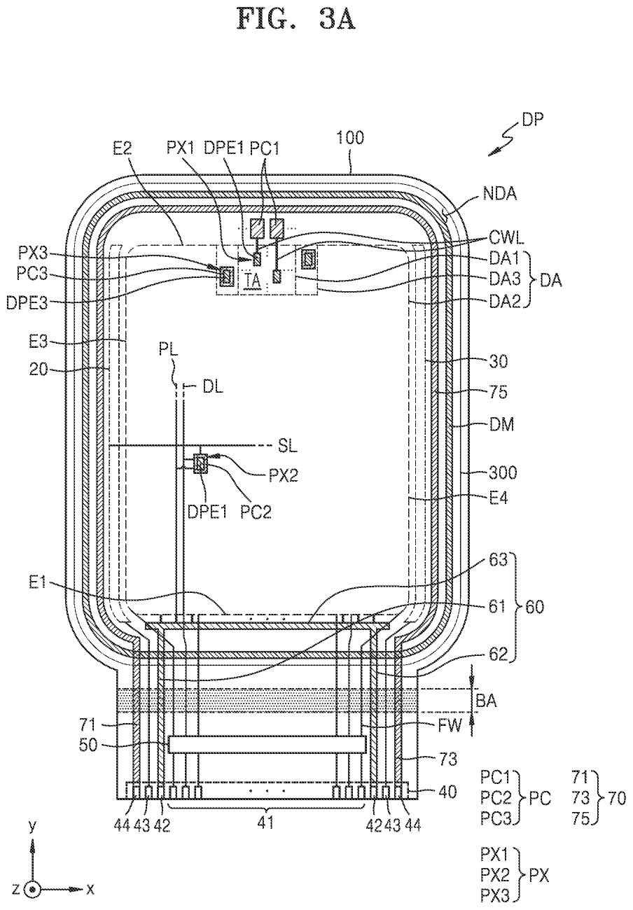

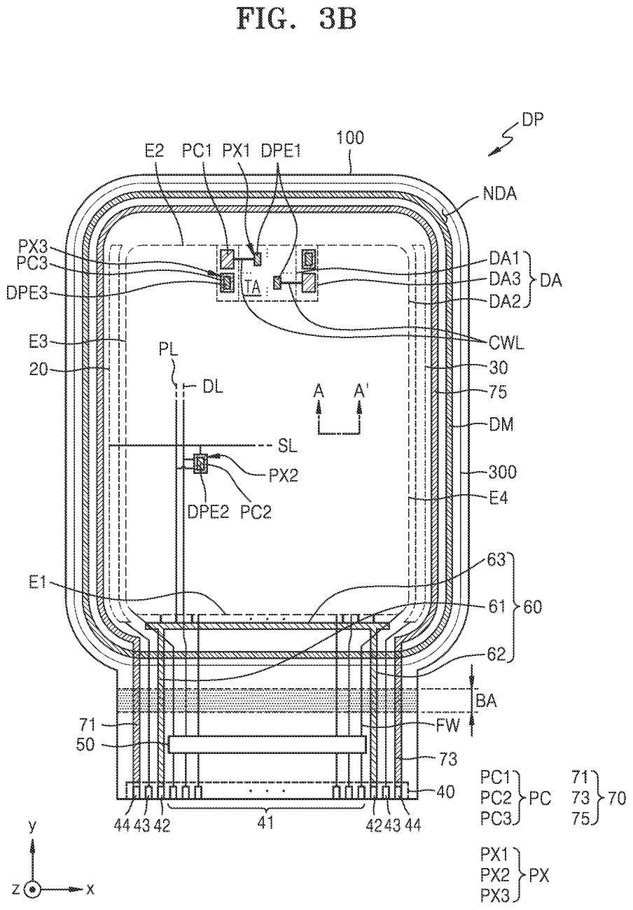

FIGS. 3A and 3B are plan views schematically illustrating a display panel DP of a display apparatus DV according to an embodiment.

Referring to FIGS. 3A and 3B, the display panel DP may include first and second scan driver 20 and 30, a terminal portion 40, a data driver 50, and a power supply line which are disposed on a substrate 100. The power supply line may include a driving voltage supply line 60 and a common voltage supply line 70.

The substrate 100 may include a display area DA and a non-display area NDA surrounding the display area DA. A portion of the non-display area NDA may include an extend portion extending from one side of the display area DA (e.g., extending in the −y direction). The terminal portion 40, the data driver 50, the driving voltage supply line 60, a fan-out wiring FW, and the like may be arranged in the extended non-display area NDA. In an embodiment, the width of the extended non-display area NDA in the x direction may be less than the width of the display area DA in the x direction.

The substrate 100 may include a bending area BA in which a portion of the extended non-display area NDA is bent. As the extended non-display area NDA is folded with respect to the bending area BA, the extended non-display area NDA may partially overlap the display area DA. With this structure, the extended non-display area NDA is not recognized by the user, or even when the extended non-display area NDA is recognized, the recognized area may be minimized.

A plurality of sub-pixels PX may be disposed in the display area DA. The sub-pixel circuits PC configured to drive the sub-pixels PX disposed on the display area DA may each be connected to a signal line or a voltage line configured to control operation and luminance of the display element. For example, FIGS. 3A and 3B illustrate a scan line SL extending in the first direction (e.g., the x direction) and a data line DL as the signal line and a driving voltage line PL as the voltage line extending in the second direction (e.g., the y direction).

A plurality of second sub-pixels PX2 may be disposed in the second display area DA2. The second sub-pixels PX2 may include an organic light-emitting diode as a light-emitting element. The second sub-pixel circuits PC2 configured to respectively drive the second sub-pixels PX2 may be disposed in the second display area DA2. The second sub-pixel circuit PC2 may be disposed to overlap the corresponding second sub-pixel PX2. The second sub-pixels PX2 may each emit, for example, red light, green light, blue light, or white light. The second display area DA2 may be covered with the encapsulation member and may be protected from external air or moisture.

As described above, the first display area DA1 and the third display area DA3 may be arranged on one side of the second display area DA2 or may be surrounded by the second display area DA2. The third display area DA3 may at least partially surround the first display area DA1. A plurality of first sub-pixels PX1 may be in the first display area DA1, and a plurality of third sub-pixels PX3 may be in the third display area DA3. The first sub-pixels PX1 and the third sub-pixels PX3 may each include an organic light-emitting diode as a light-emitting element. The first sub-pixels PX1 and the third sub-pixels PX3 may each emit, for example, red light, green light, blue light, or white light. The first display area DA1 and the third display area DA3 may be covered with the encapsulation member and may be protected from external air or moisture.

The first sub-pixel PX1 may be disposed in the first display area DA1 and the third sub-pixel PX3 may be disposed in the third display area DA3. That is, this may mean that the first sub-pixel PX1 substantially emits light in the first display area DA1 and the third sub-pixel PX3 substantially emits light in the third display area DA3.

Referring to FIG. 3A, because the first display element DPE1 constituting the first sub-pixel PX1 is disposed in the first display area DA1 and the first sub-pixel circuit PC1 is disposed in the third display area DA3, the first display element DPE1 and the first sub-pixel circuit PC1 may be connected to each other by the connection wiring CWL.

In another embodiment, referring to FIG. 3B, because the first display element DPE1 constituting the first sub-pixel PX1 is disposed in the first display area DA1 and the first sub-pixel circuit PC1 is disposed in the non-display area NDA, the first display element DPE1 and the first sub-pixel circuit PC1 may be connected to each other by the connection wiring CWL.

As described above, when the first sub-pixel circuit PC1 including the transistors and the storage capacitor connected to the signal lines and the voltage lines is disposed in the third display area DA3 or the non-display area NDA and the first display element DPE1 is disposed in the first display area DA1, the area of the transmission area TA may be increased while the resolution in the first display area DA1 is maintained.

The first to third sub-pixel circuits PC1, PC2, and PC3 configured to drive the first to third sub-pixels PX1, PX2, and PX3 may be electrically connected to external circuits arranged in the non-display area NDA. The first and second scan drivers 20 and 30, the terminal portion 40, the data driver 50, the driving voltage supply line 60, and the common voltage supply line 70 may be disposed in the non-display area NDA.

The first scan driver 20 and the second scan driver 30 may be configured to generate and transmit a scan signal to each of the sub-pixel circuits PC through the scan line SL. In an embodiment, the first scan driver 20 or the second scan driver 30 may be configured to apply an emission control signal to each of the sub-pixel circuits PC through an emission control line. In an embodiment, a structure in which the first and second scan drivers 20 and 30 are disposed on both sides of the display area DA is illustrated, but in another embodiment, the scan driver may be disposed on only one side of the display area DA. The second scan driver 30 may be arranged to be symmetrical with the first scan driver 20 with respect to the display area DA.

The data driver 50 may be configured to generate and transmit a data signal to each of the sub-pixel circuits PC through the data line DL. The data driver 50 may be disposed on one side of the display area DA and may be disposed in the extended non-display area NDA below the display area DA in the −y direction. FIGS. 3A and 3B illustrate that the data driver 50 is disposed on the substrate 100, but in another embodiment, the data driver 50 may be disposed on a flexible printed circuit board connected to the terminal portion 40.

The terminal portion 40 may be arranged at one end portion of the substrate 100 and may include a plurality of terminals 41, 42, 43, and 44. The terminal portion 40 may be exposed without being covered with an insulating layer and may be electrically connected to a controller such as an integrated circuit (IC) chip or a flexible printed circuit board. Control signals of the controller may be provided to the first scan driver 20, the second scan driver 30, the data driver 50, the driving voltage supply line 60, and the common voltage supply line 70 through the terminal portion 40.

The driving voltage supply line 60 may be in the non-display area NDA. The driving voltage supply line 60 may be configured to provide a driving voltage ELVDD to each of the sub-pixels PX. In an embodiment, the driving voltage supply line 60 may include a first driving voltage supply line 61, a second driving voltage supply line 62, and a third driving voltage supply line 63. The third driving voltage supply line 63 may extend in the first direction (e.g., the x direction) and the first and second driving voltage supply lines 61 and 62 may extend in the second direction (e.g., the y direction). For example, the third driving voltage supply line 63 may be arranged along a first edge E1 of the display area DA. In an embodiment, the first driving voltage supply line 61, the second driving voltage supply line 62, and the third driving voltage supply line 63 may be integrally formed as a single body. For example, the driving voltage supply line 60 may have a “IT” (pie) shape as a single body. However, the disclosure is not limited thereto.

The driving voltage supply line 60 may be disposed in the non-display area NDA and may be connected to a plurality of driving voltage lines PL extending to the display area DA in the second direction (e.g., the y direction). For example, the third driving voltage supply line 63 may be connected to the driving voltage line PL crossing the display area DA in the second direction (e.g., the y direction).

The common voltage supply line 70 may be disposed in the non-display area NDA and may be configured to provide a common voltage ELVSS to each of the sub-pixels PX. The common voltage supply line 70 may include a first common voltage supply line 71 and a second common voltage supply line 73 which are arranged adjacent to the first edge E1 of the display area DA. The first common voltage supply line 71 and the second common voltage supply line 73 may each extend in the second direction (e.g., the y direction). In addition, the first common voltage supply line 71 and the second common voltage supply line 73 may be spaced apart from each other in the first direction (e.g., the x direction) crossing the second direction (e.g., the y direction). The first common voltage supply line 71 and the second common voltage supply line 73 may be disposed on both sides of the first edge E1 of the display area DA. However, the disclosure is not limited thereto. The common voltage supply line 70 may further include a third common voltage supply line between the first common voltage supply line 71 and the second common voltage supply line 73. In a case where the common voltage supply line 70 includes the third common voltage supply line disposed between the first common voltage supply line 71 and the second common voltage supply line 73, current density when current is applied thereto may be lowered and heat generation may be suppressed compared to a case where only the first common voltage supply line 71 and the second common voltage supply line 73 are provided.

The first common voltage supply line 71 and the second common voltage supply line 73 may be connected to each other by a body portion 75 extending along a second edge E2, a third edge E3, and a fourth edge E4 of the display area DA. In an embodiment, the first common voltage supply line 71, the second common voltage supply line 73, and the body portion 75 may be integrally formed as a single body.

In some embodiments, a dam DM may be disposed in the non-display area NDA. The dam DM may be disposed to surround the periphery of the display area DA. The dam DM may be disposed outside the common voltage supply line 70 or may be disposed to partially overlap the common voltage supply line 70.

A thin-film encapsulation layer 300 may be disposed in the display area DA and cover the sub-pixels PX. A portion of the thin-film encapsulation layer 300 may extend to the non-display area NDA. The thin-film encapsulation layer 300 may have a multilayer structure including at least one organic encapsulation layer and at least one inorganic encapsulation layer. The dam DM may prevent a material for forming the organic encapsulation layer included in the thin-film encapsulation layer 300 from overflowing to the edge of the substrate 100 and may define the formation position of the organic encapsulation layer.

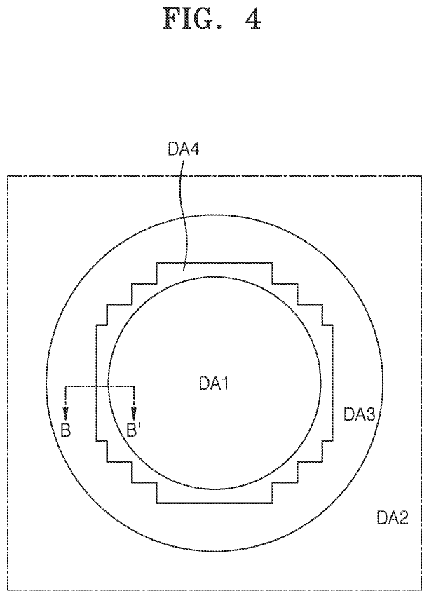

FIG. 4 is a partial enlarged plan view schematically illustrating a display apparatus DV according to an embodiment. Specifically, FIG. 4 is an enlarged plan view schematically illustrating a portion of the display apparatus DV with respect to display areas according to an embodiment.

Referring to FIG. 4, the display apparatus DV may include the first display area DA1, a second display area DA2 surrounding at least a portion of the first display area DA1, and a third display area DA3 disposed between the first display area DA1 and the second display area DA2. In other words, the third display area DA3 may surround at least a portion of the first display area DA1, and the second display area DA2 may surround at least a portion of the third display area DA3.

In an embodiment, FIG. 4 illustrates that the first display area DA1 of the display apparatus DV has a circular shape, but the disclosure is not limited thereto. In another embodiment, the first display area DA1 of the display apparatus DV may have an elliptical shape or a rectangular shape.

The fourth display area DA4 may be disposed at a boundary between the first display area DA1 and the third display area DA3. As described above, the first display area DA1 may be an area overlapping the component (see COM of FIG. 2A) and may include the transmission area (see TA of FIG. 1A) in order to secure light transmittance. In order to improve the visibility of the display apparatus DV, the first sub-pixel (see PX1 of FIG. 1A) may also be in the first display area DA1. In other words, the first display element (see DPE1 of FIG. 2A) may also be in the first display area DA1. The first sub-pixel circuit (see PC1 of FIG. 2A) configured to allow the first display element (see DPE1 of FIG. 2A) to emit light may be disposed in the third display area DA3 in order to ensure light transmittance of the first display area DA1. The first display element (see DPE1 of FIG. 2A) disposed in the first display area DA1 and the first sub-pixel circuit (see PC1 of FIG. 2A) disposed in the third display area DA3 may be electrically connected to each other by the connection wiring (see CWL of FIG. 2A). Because the fourth display area DA4 is located at a boundary between the first display area DA1 and the third display area DA3, the fourth display area DA4 may be an area in which the connection wiring (see CWL of FIG. 2A) is arranged. In other words, the fourth display area DA4 may be located in the middle of the first display area DA1 and the third display area DA3, and the fourth display area DA4 may be an area in which the connection wiring (see CWL of FIG. 2A) is arranged.

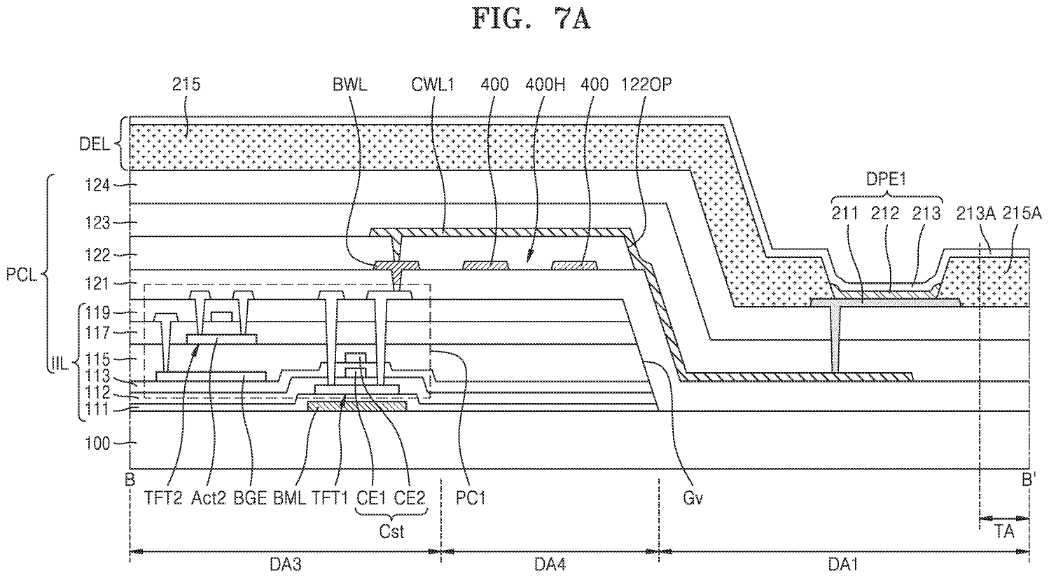

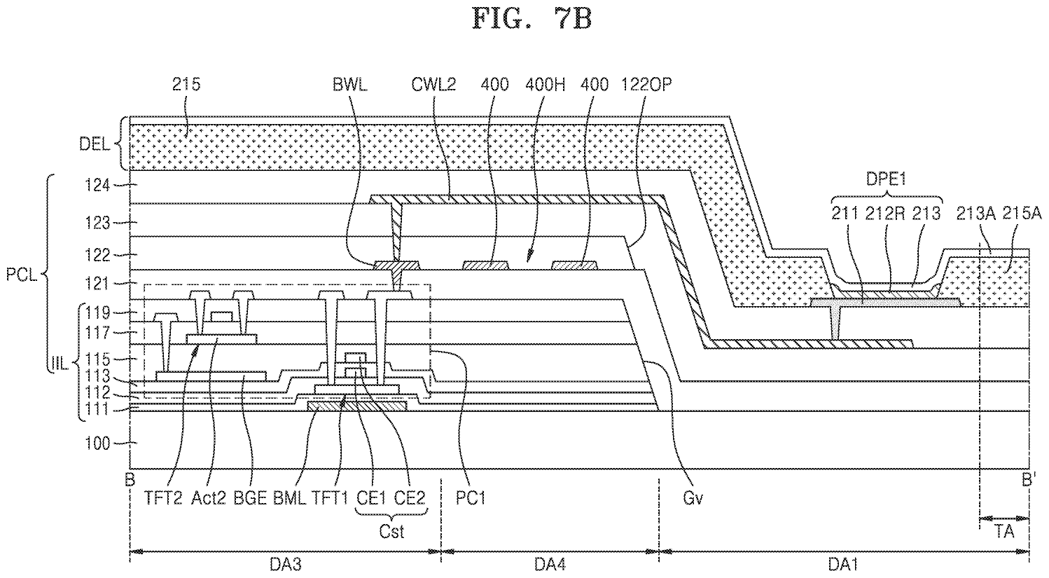

In an embodiment, the connection wiring and the conductive pattern layer may be disposed in the fourth display area DA4. The scan line of the display apparatus DV may bypass the first display area in order to secure light transmittance of the first display area DA1. In other words, the scan line of the display apparatus DV may be disposed outside the first display area along the edge of the first display area DA1. Data coupling may occur between the scan line bypassing the first display area DA1 and the connection wiring CWL disposed adjacent thereto. In order to prevent occurrence of data coupling between the scan line bypassing the first display area DA1 and the connection wiring CWL disposed adjacent thereto, the conductive pattern layer may be disposed between the scan line bypassing the first display area DA1 and the connection wiring CWL. This is described below in detail with reference to FIGS. 7A and 7B.

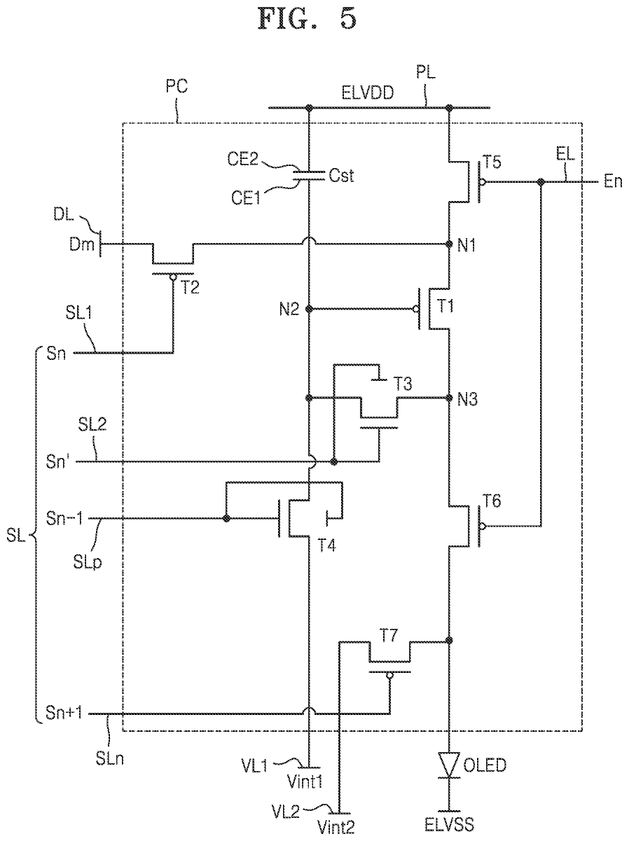

FIG. 5 is an equivalent circuit diagram schematically illustrating a sub-pixel circuit PC electrically connected to an organic light-emitting diode OLED corresponding to a sub-pixel of a display apparatus according to an embodiment.

The sub-pixel circuit PC illustrated in FIG. 5 may correspond to each of the first sub-pixel circuit PC1, the second sub-pixel circuit PC2, and the third sub-pixel circuit PC3 which have been described above with reference to FIGS. 3A and 3B.

The organic light-emitting diode OLED illustrated in FIG. 5 which is a display element may correspond to each of the first display element DPE1, the second display element DPE2, and the third display element DPE3 which have been described above with reference to FIGS. 3A and 3B.

Referring to FIG. 5, the sub-pixel circuit PC may include a plurality of thin-film transistors T1 to T7 and a storage capacitor Cst. The thin-film transistors T1 to T7 and the storage capacitor Cst may be connected to signal lines SL1, SL2, SLp, SLn, EL, and DL, a first initialization voltage line VL1, a second initialization voltage line VL2, and a driving voltage line PL. At least one of these lines, for example, the driving voltage line PL, may be shared by neighboring sub-pixel circuits PC.

In an embodiment, the thin-film transistors T1 to T7 may include a driving transistor T1, a switching transistor T2, a compensation transistor T3, a first initialization transistor T4, an operation control transistor T5, an emission control transistor T6, and a second initialization transistor T7. However, the disclosure is not limited thereto.

The organic light-emitting diode OLED may include a pixel electrode and an opposite electrode. The pixel electrode of the organic light-emitting diode OLED may be connected to the driving transistor T1 through the emission control transistor T6 and configured to receive a driving current. The opposite electrode may be configured to receive a common voltage ELVSS. The organic light-emitting diode OLED may be configured to emit light having a luminance corresponding to the driving current.

Some of the thin-film transistors T1 to T7 may be n-channel metal-oxide silicon field effect transistors (MOSFETs), that is, NMOS transistors, and the others thereof may be p-channel MOSFETs, that is, PMOS transistors. For example, the compensation transistor T3 and the first initialization transistor T4 of the thin-film transistors T1 to T7 may be NMOS transistors, and the others thereof may be PMOS transistors. Alternatively, the compensation transistor T3, the first initialization transistor T4, and the second initialization transistor T7 of the thin-film transistors T1 to T7 may be NMOS transistors, and the others thereof may be PMOS transistors. Alternatively, all the thin-film transistors T1 to T7 may be NMOS transistors or PMOS transistors. The thin-film transistors T1 to T7 may each include amorphous silicon or polysilicon. When necessary, the thin-film transistors, which are NMOS transistors, may each include an oxide semiconductor. Hereinafter, for convenience, a case where the compensation transistor T3 and the first initialization transistor T4 are NMOS transistors including oxide semiconductor and the others are PMOS transistors is described.

The signal lines may include a first scan line SL1, a second scan line SL2, a previous scan line SLp, a next scan line SLn, an emission control line EL, and a data line DL. However, the disclosure is not limited thereto. In addition, the first scan line SL1 may be configured to transmit a first scan signal Sn. The second scan line SL2 may be configured to transmit a second scan signal Sn′. The previous scan line SLp may be configured to transmit a previous scan signal Sn-1 to the first initialization transistor T4. The next scan line SLn may be configured to transmit a next scan signal Sn+1 to the second initialization transistor T7. The emission control line EL may be configured to transmit an emission control signal En to the operation control transistor T5 and the emission control transistor T6. The data line DL may be configured to transmit a data signal Dm. The driving voltage line PL may be configured to transmit a driving voltage ELVDD to the driving transistor T1. The first initialization voltage line VL1 may be configured to transmit a first initialization voltage Vint1 for initializing the driving transistor T1. The second initialization voltage line VL2 may be configured to transmit a second initialization voltage Vint2 for initializing the pixel electrode of the organic light-emitting diode OLED.

A driving gate electrode of the driving transistor T1 may be connected to the storage capacitor Cst through a second node N2. One of a source region and a drain region of the driving transistor T1 may be connected through a first node N1 to the driving voltage line PL via the operation control transistor T5. The other of the source region and the drain region of the driving transistor T1 may be electrically connected through a third node N3 to the pixel electrode of the organic light-emitting diode OLED via the emission control transistor T6. The driving transistor T1 may be configured to receive the data signal Dm according to the switching operation of the switching transistor T2 and supply a driving current to the organic light-emitting diode OLED. That is, the driving transistor T1 may be configured to control the amount of current flowing from the first node N1 electrically connected to the driving voltage line PL to the organic light-emitting diode OLED in response to the voltage applied to the second node N2 which is changed by the data signal Dm.

A switching gate electrode of the switching transistor T2 may be connected to the first scan line SL1 configured to transmit the first scan signal Sn. One of a source region and a drain region of the switching transistor T2 may be connected to the data line DL. The other of the source region and the drain region of the switching transistor T2 may be connected to the driving transistor T1 through the first node N1 and connected to the driving voltage line PL via the operation control transistor T5. The switching transistor T2 may be configured to transmit the data signal Dm from the data line DL to the first node N1 in response to the voltage applied to the first scan line SL1. That is, the switching transistor T2 may be configured to be turned on in response to the first scan signal Sn received through the first scan line SL1 and perform a switching operation of transmitting the data signal Dm from the data line DL to the driving transistor T1 through the first node N1. A compensation gate electrode of the compensation transistor T3 may be connected to the second scan line SL2. One of a source region and a drain region of the compensation transistor T3 may be connected through the third node N3 to the pixel electrode of the organic light-emitting diode OLED via the emission control transistor T6. The other of the source region and the drain region of the compensation transistor T3 may be connected through the second node N2 to a first capacitor electrode CE1 of the storage capacitor Cst and the driving gate electrode of the driving transistor T1. The compensation transistor T3 may be configured to be turned on in response to the second scan signal Sn′ received through the second scan line SL2 and diode-connect the driving transistor T1.

A first initialization gate electrode of the first initialization transistor T4 may be connected to the previous scan line SLp. One of a source region and a drain region of the first initialization transistor T4 may be connected to the first initialization voltage line VL1. The other of the source region and the drain region of the first initialization transistor T4 may be connected through the second node N2 to the first capacitor electrode CE1 of the storage capacitor Cst and the driving gate electrode of the driving transistor T1. The first initialization transistor T4 may be configured to apply the first initialization voltage Vint1 from the first initialization voltage line VL1 to the second node N2 in response to the voltage applied to the previous scan line SLp. That is, the first initialization transistor T4 may be configured to be turned on in response to the previous scan signal Sn-1 received through the previous scan line SLp and perform an initialization operation of transmitting the first initialization voltage Vint1 to the driving gate electrode of the driving transistor T1 to initialize the voltage of the driving gate electrode of the driving transistor T1.

An operation control gate electrode of the operation control transistor T5 may be connected to the emission control line EL. One of a source region and a drain region of the operation control transistor T5 may be connected to the driving voltage line PL. The other of the source region and the drain region of the operation control transistor T5 may be connected through the first node N1 to the driving transistor T1 and the switching transistor T2.

An emission control gate electrode of the emission control transistor T6 may be connected to the emission control line EL. One of a source region and a drain region of the emission control transistor T6 may be connected through the third node N3 to the driving transistor T1 and the compensation transistor T3. The other of the source region and the drain region of the emission control transistor T6 may be electrically connected to the pixel electrode of the organic light-emitting diode OLED.

The operation control transistor T5 and the emission control transistor T6 may be configured to be simultaneously turned on in response to the emission control signal En received through the emission control line EL and transmit the driving voltage ELVDD to the organic light-emitting diode OLED so that the driving current flows through the organic light-emitting diode OLED.

A second initialization gate electrode of the second initialization transistor T7 may be connected to the next scan line SLn. One of a source region and a drain region of the second initialization transistor T7 may be connected to the pixel electrode of the organic light-emitting diode OLED. The other of the source region and the drain region of the second initialization transistor T7 may be connected to the second initialization voltage line VL2 and configured to receive the second initialization voltage Vint2. The second initialization transistor T7 may be configured to be turned on in response to the next scan signal Sn+1 received through the next scan line SLn and initialize the pixel electrode of the organic light-emitting diode OLED. The next scan line SLn may be a first scan line of another sub-pixel circuit adjacent to the sub-pixel circuit PC illustrated in FIG. 4 and electrically connected to the same data line DL.

The storage capacitor Cst may include the first capacitor electrode CE1 and the second capacitor electrode CE2. The first capacitor electrode CE1 of the storage capacitor Cst maybe connected to the driving gate electrode of the driving transistor T1 through the second node N2, and the second capacitor electrode CE2 of the storage capacitor Cst may be connected to the driving voltage line PL. The storage capacitor Cst may store electric charges corresponding to the difference between the driving gate electrode voltage of the driving transistor T1 and the driving voltage ELVDD.

Detailed operations of the sub-pixel circuit PC and the organic light-emitting diode OLED as the display element according to an embodiment are as follows.

During an initialization period, when the previous scan signal Sn-1 is supplied through the previous scan line SLp, the first initialization transistor T4 may be turned on in response to the previous scan signal Sn-1 and the first node which is connected to the driving gate electrode of the driving transistor T1 may be initialized by the first initialization voltage Vint1 supplied from the first initialization voltage line VL1.

During a data programming period, when the first scan signal Sn and the second scan signal Sn′ are respectively supplied through the first scan line SL1 and the second scan line SL2, the switching transistor T2 and the compensation transistor T3 may be respectively turned on in response to the first scan signal Sn and the second scan signal Sn′. The driving transistor T1 may be diode-connected by the turned-on compensation transistor T3 and may be forward biased. A compensation voltage reduced from the data signal Dm supplied from the data line DL by the threshold voltage (Vth) of the driving transistor T1 (Dm+Vth, where Vth is a negative value) may be applied to the driving gate electrode of the driving transistor T1. The driving voltage ELVDD and the compensation voltage (Dm+Vth) may be applied to both ends of the storage capacitor Cst, and electric charges corresponding to the voltage difference between both ends of the storage capacitor Cst may be stored in the storage capacitor Cst.

During an emission period, the operation control transistor T5 and the emission control transistor T6 may be turned on in response to the emission control signal En supplied from the emission control line EL. The driving current corresponding to the difference between the voltage of the driving gate electrode of the driving transistor T1 and the driving voltage ELVDD may be generated, and the driving current may be supplied to the organic light-emitting diode OLED through the emission control transistor T6.

As described above, some of the thin-film transistors T1 to T7 may each include an oxide semiconductor. For example, the compensation transistor T3 and the first initialization transistor T4 may each include an oxide semiconductor. However, the disclosure is not limited thereto.

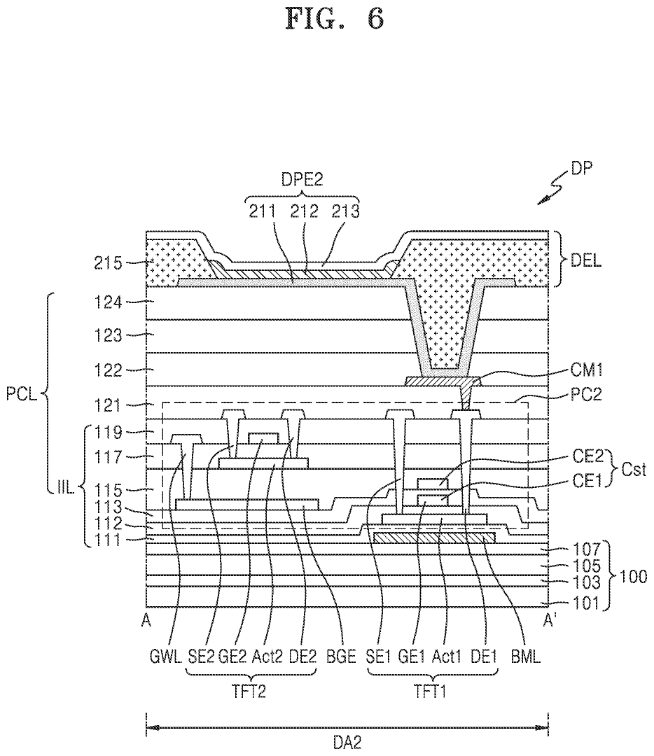

FIG. 6 is a cross-sectional view of a portion of the display panel DP of the display apparatus of FIG. 3A taken along line A-A′ of FIG. 3A according to an embodiment.

Referring to FIG. 6, the display panel DP may include a substrate 100, a pixel circuit layer PCL, and a display element layer DEL.

The substrate 100 may include glass or polymer resin. In an embodiment, the substrate 100 may have a structure in which a base layer including polymer resin and a barrier layer including an inorganic insulating material, such as silicon oxide or silicon nitride, are alternately stacked. For example, the substrate 100 may include a first base layer 101, a first barrier layer 103, a second base layer 105, and a second barrier layer 107, which are sequentially stacked in this stated order. The first base layer 101 and the second base layer 105 may each include polymer resin, and the first barrier layer 103 and the second barrier layer 107 may each include an inorganic insulating material. The polymer resin may include polyethersulfone, polyarylate, polyether imide, polyethylene naphthalate, polyethylene terephthalate, polyphenylene sulfide, polyimide, polycarbonate, cellulose triacetate, or cellulose acetate propionate.

The pixel circuit layer PCL may be disposed on the substrate 100. The pixel circuit layer PCL may include a second sub-pixel circuit PC2, an inorganic insulating layer IIL, a first organic insulating layer 121, a second organic insulating layer 122, a third organic insulating layer 123, and a fourth organic insulating layer 124. In an embodiment, the inorganic insulating layer IIL may include a buffer layer 111, a first gate insulating layer 112, a second gate insulating layer 113, a first inorganic insulating layer 115, a second inorganic insulating layer 117, and an interlayer insulating layer 119.

The second sub-pixel circuit PC2 may be disposed in the second display area DA2. As described above with reference to FIG. 5, the second sub-pixel circuit PC2 may include a plurality of transistors and a storage capacitor. In this regard, FIG. 6 illustrates a first thin-film transistor TFT1, a second thin-film transistor TFT2, and a storage capacitor Cst. The first thin-film transistor TFT1 may include a first semiconductor layer Act1, a first gate electrode GE1, a first source electrode SE1, and a first drain electrode DE1. The second thin-film transistor TFT2 may include a second semiconductor layer Act2, a second gate electrode GE2, a second source electrode SE2, and a second drain electrode DE2. The storage capacitor Cst may include a first capacitor electrode CE1 and a second capacitor electrode CE2.

The buffer layer 111 may be disposed on the substrate 100. The buffer layer 111 may reduce or block infiltration of foreign material, moisture, or ambient air from below the substrate 100. The buffer layer 111 may include an inorganic material such as silicon oxide, silicon oxynitride, or silicon nitride and may include a single layer or layers including the inorganic material described above.

The first semiconductor layer Act1 may include a silicon semiconductor. The first semiconductor layer Act1 may include polysilicon. Alternatively, the first semiconductor layer Act1 may include amorphous silicon. In some embodiments, the first semiconductor layer Act1 may include an oxide semiconductor or an organic semiconductor. The first semiconductor layer Act1 may include a channel region, and a drain region and a source region respectively disposed on both sides of the channel region. The first gate electrode GE1 may overlap the channel region.

The first gate electrode GE1 may overlap the first semiconductor layer Act1. The first gate electrode GE1 may include a low-resistance metal material. The first gate electrode GE1 may include a conductive material including molybdenum (Mo), aluminum (Al), copper (Cu), titanium (Ti), and the like, and may include a single layer or layers including the conductive material described above.

The first gate insulating layer 112 may be disposed between the first semiconductor layer Act1 and the first gate electrode GE1. Accordingly, the first semiconductor layer Act1 may be insulated from the first gate electrode GE1. The first gate insulating layer 112 may include an inorganic insulating material such as silicon oxide, silicon nitride, silicon oxynitride, aluminum oxide, titanium oxide, tantalum oxide, hafnium oxide, and/or zinc oxide.

The second gate insulating layer 113 may cover the first gate electrode GE1. The second gate insulating layer 113 may be disposed on the first gate electrode GE1. Similar to the first gate insulating layer 112, the second gate insulating layer 113 may include an inorganic insulating material such as silicon oxide, silicon nitride, silicon oxynitride, aluminum oxide, titanium oxide, tantalum oxide, hafnium oxide, and/or zinc oxide.

The second capacitor electrode CE2 may be disposed on the second gate insulating layer 113. The second capacitor electrode CE2 may overlap the first gate electrode GE1 disposed therebelow. In this case, the second capacitor electrode CE2 and the first gate electrode GE1 may overlap each other with the second gate insulating layer 113 disposed therebetween to form the storage capacitor Cst. That is, the first gate electrode GE1 of the first thin-film transistor TFT1 may function as the first capacitor electrode CE1 of the storage capacitor Cst.

As described above, the storage capacitor Cst may overlap the first thin-film transistor TFT1. In some embodiments, the storage capacitor Cst may not overlap the first thin-film transistor TFT1.

The second capacitor electrode CE2 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may include a single layer or layers including the material described above.

The first inorganic insulating layer 115 may cover the second capacitor electrode CE2. In an embodiment, the first inorganic insulating layer 115 may cover the first gate electrode GE1. The first inorganic insulating layer 115 may include silicon oxide, silicon nitride, silicon oxynitride, aluminum oxide, titanium oxide, tantalum oxide, hafnium oxide, or zinc oxide. The first inorganic insulating layer 115 may include a single layer or layers including the inorganic insulating material described above.

The second semiconductor layer Act2 may be disposed on the first inorganic insulating layer 115. In an embodiment, the second semiconductor layer Act2 may include a channel region, and a source region and a drain region respectively disposed on both sides of the channel region. The second semiconductor layer Act2 may include an oxide semiconductor. For example, the second semiconductor layer Act2 may include a Zn oxide-based material, such as Zn oxide, In—Zn oxide, or Ga—In—Zn oxide. Alternatively, the second semiconductor layer Act2 may include In—Ga—Zn—O (IGZO), In—Sn—Zn—O (ITZO), or In—Ga—Sn—Zn—O (IGTZO) semiconductor in which a metal, such as indium (In), gallium (Ga), or tin (Sn), is included in zinc oxide (ZnO).

The source region and the drain region of the second semiconductor layer Act2 may be formed by adjusting the carrier concentration of the oxide semiconductor to make it conductive. For example, the source region and the drain region of the second semiconductor layer Act2 may be formed by increasing carrier concentration through plasma treatment using hydrogen-based gas, fluorine-based gas, or any combination thereof with respect to an oxide semiconductor.

The second inorganic insulating layer 117 may cover the second semiconductor layer Act2. The second inorganic insulating layer 117 may be disposed between the second semiconductor layer Act2 and the second gate electrode GE2. In an embodiment, the second inorganic insulating layer 117 may be disposed on the entire substrate 100. In another embodiment, the second inorganic insulating layer 117 may be patterned along the shape of the second gate electrode GE2. The second inorganic insulating layer 117 may include silicon oxide, silicon nitride, silicon oxynitride, aluminum oxide, titanium oxide, tantalum oxide, hafnium oxide, or zinc oxide. The second inorganic insulating layer 117 may include a single layer or layers including the inorganic insulating material described above.

The second gate electrode GE2 may be disposed on the second inorganic insulating layer 117. The second gate electrode GE2 may overlap the second semiconductor layer Act2. The second gate electrode GE2 may overlap the channel region of the second semiconductor layer Act2. The second gate electrode GE2 may include a conductive material including molybdenum (Mo), aluminum (Al), copper (Cu), titanium (Ti), and the like, and may include a single layer or layers including the conductive material described above.

The interlayer insulating layer 119 may cover the second gate electrode GE2. The interlayer insulating layer 119 may include silicon oxide, silicon nitride, silicon oxynitride, aluminum oxide, titanium oxide, tantalum oxide, hafnium oxide, or zinc oxide. The interlayer insulating layer 119 may include a single layer or layers including the inorganic insulating material described above.

The first source electrode SE1 and the first drain electrode DE1 may be disposed on the interlayer insulating layer 119. The first source electrode SE1 and the first drain electrode DE1 may be connected to the first semiconductor layer Act1. The first source electrode SE1 and the first drain electrode DE1 may be connected to the first semiconductor layer Act1 through contact holes formed through the interlayer insulating layer 119, the second inorganic insulating layer 117, the first inorganic insulating layer 115, the second gate insulating layer 113 and the first gate insulating layer 112.

The second source electrode SE2 and the second drain electrode DE2 may be disposed on the interlayer insulating layer 119. The second source electrode SE2 and the second drain electrode DE2 may be electrically connected to the second semiconductor layer Act2. The second source electrode SE2 and the second drain electrode DE2 may be electrically connected to the second semiconductor layer Act2 through contact holes formed through the interlayer insulating layer 119 and the second inorganic insulating layer 117.

The first source electrode SE1, the first drain electrode DE1, the second source electrode SE2, and the second drain electrode DE2 may each include a material having good conductivity. The first source electrode SE1, the first drain electrode DE1, the second source electrode SE2, and the second drain electrode DE2 may each include a conductive material including molybdenum (Mo), aluminum (Al), copper (Cu), titanium (Ti), and the like, and may include a single layer or layers including the conductive material described above. In an embodiment, the first source electrode SE1, the first drain electrode DE1, the second source electrode SE2, and the second drain electrode DE2 may each have a multilayer structure of Ti/Al/Ti.

The first thin-film transistor TFT1 including the silicon semiconductor as the first semiconductor layer Act1 may have high reliability. For example, the first thin-film transistor TFT1 may be the driving transistor (see T1 of FIG. 4). In this case, a high-quality display panel DP may be implemented.

Because the oxide semiconductor has high carrier mobility and low leakage current, the voltage drop may not be great even when the driving time is long. That is, the color change of the image according to the voltage drop is not great even during low-frequency driving. Therefore, the low-frequency driving is possible. As described above, in the case of the oxide semiconductor, the leakage current is small. Therefore, by employing the oxide semiconductor in at least one of the transistors other than the driving transistor, leakage current may be prevented and power consumption may be reduced. For example, the second thin-film transistor TFT2 may be the compensation transistor (see T3 of FIG. 4).

A bottom gate electrode BGE may be disposed below the second semiconductor layer Act2. In an embodiment, the bottom gate electrode BGE may be disposed between the second gate insulating layer 113 and the first inorganic insulating layer 115. In an embodiment, the bottom gate electrode BGE may be configured to receive a gate signal which is the same gate signal applied to the second gate electrode GE2. In this case, the second thin-film transistor TFT2 may have a double gate electrode structure in which gate electrodes are disposed above and below the second semiconductor layer Act2.

In an embodiment, a gate wiring GWL may be disposed between the second inorganic insulating layer 117 and the interlayer insulating layer 119. In an embodiment, the gate wiring GWL may be electrically connected to the bottom gate electrode BGE through contact holes formed through the first inorganic insulating layer 115 and the second inorganic insulating layer 117.

In an embodiment, a bottom metal layer BML may be disposed between the substrate 100 and the second sub-pixel circuit PC2 overlapping the second display area DA2. In an embodiment, the bottom metal layer BML may overlap the first thin-film transistor TFT1. A constant voltage may be applied to the bottom metal layer BML. Because the bottom metal layer BML is disposed below the first thin-film transistor TFT1, the first thin-film transistor TFT1 may be less affected by surrounding interference signals and thus reliability may be improved.

The first organic insulating layer 121 may be disposed to cover the first source electrode SE1, the first drain electrode DE1, the second source electrode SE2, and the second drain electrode DE2. The first organic insulating layer 121 may include an organic material. For example, the first organic insulating layer 121 may include an organic material selected from general-purpose polymer such as polymethylmethacrylate (PMMA) or polystyrene (PS), polymer derivatives having a phenolic group, acrylic polymer, imide-based polymer, aryl ether-based polymer, amide-based polymer, fluorine-based polymer, p-xylene-based polymer, vinyl alcohol-based polymer, and any blend thereof.

A first connection electrode CM1 may be disposed on the first organic insulating layer 121. In this case, the first connection electrode CM1 may be connected to the first drain electrode DE1 or the first source electrode SE1 through a contact hole formed through the first organic insulating layer 121.

The first connection electrode CM1 may include a material having good conductivity. The first connection electrode CM1 may include a conductive material including molybdenum (Mo), aluminum (Al), copper (Cu), titanium (Ti), and the like, and may include a single layer or layers including the conductive material described above. In an embodiment, the first connection electrode CM1 may have a multilayer structure of Ti/Al/Ti.

The second organic insulating layer 122, the third organic insulating layer 123, and the fourth organic insulating layer 124 may be disposed to cover the first connection electrode CM1. The second organic insulating layer 122, the third organic insulating layer 123, and the fourth organic insulating layer 124 may each include an organic material. For example, the second organic insulating layer 122, the third organic insulating layer 123, and the fourth organic insulating layer 124 may each include an organic insulating material selected from general-purpose polymer such as PMMA or PS, polymer derivatives having a phenolic group, acrylic polymer, imide-based polymer, aryl ether-based polymer, amide-based polymer, fluorine-based polymer, p-xylene-based polymer, vinyl alcohol-based polymer, and any blend thereof.

Although FIG. 6 illustrates that the pixel circuit layer PCL includes the first organic insulating layer 121, the second organic insulating layer 122, the third organic insulating layer 123, and the fourth organic insulating layer 124, the disclosure is not limited thereto. For example, at least one of the first organic insulating layer 121, the second organic insulating layer 122, the third organic insulating layer 123, or the fourth organic insulating layer 124 may be omitted.

The display element layer DEL may be disposed on the pixel circuit layer PCL. The display element layer DEL may include a display element. In an embodiment, the display element layer DEL may include a second display element DPE2 disposed in the second display area DA2. The second display element DPE2 may be an organic light-emitting diode. The second display element DPE2 may be disposed on the fourth organic insulating layer 124.

The second display element DPE2 may be electrically connected to the second sub-pixel circuit PC2. In the second display area DA2, the second display element DPE2 may be electrically connected to the second sub-pixel circuit PC2 to constitute the second sub-pixel PX2. In an embodiment, the second display element DPE2 may overlap the second sub-pixel circuit PC2. The second display element DPE2 may be an organic light-emitting diode and may include a pixel electrode 211, an intermediate layer 212, and an opposite electrode 213.

The pixel electrode 211 may be disposed on the fourth organic insulating layer 124. The pixel electrode 211 may be electrically connected to the first connection electrode CM1 through contact holes formed through the second organic insulating layer 122, the third organic insulating layer 123, and the fourth organic insulating layer 124.

The pixel electrode 211 may include a reflective layer including silver (Ag), magnesium (Mg), aluminum (Al), platinum (Pt), palladium (Pd), gold (Au), nickel (Ni), neodymium (Nd), iridium (Ir), chromium (Cr), or any compound thereof. Alternatively, the pixel electrode 211 may further include a conductive oxide layer above and/or below the reflective layer. The conductive oxide layer may include indium tin oxide (ITO), indium zinc oxide (IZO), zinc oxide (ZnO), indium oxide (In₂O₃), indium gallium oxide (IGO), and/or aluminum zinc oxide (AZO). In an embodiment, the pixel electrode 211 may have a three-layer structure of ITO/Ag/ITO.

A first bank layer 215 may be disposed on the pixel electrode 211. A first opening exposing at least a portion of the pixel electrode 211 may be defined in the first bank layer 215. A central portion of the pixel electrode 211 may be exposed through the first opening defined in the first bank layer 215. The first opening may define an emission area of light emitted from the first display element DPE1.

The first bank layer 215 may include an organic insulating material. In another embodiment, the first bank layer 215 may include an inorganic insulating material such as silicon nitride, silicon oxynitride, or silicon oxide. In another embodiment, the first bank layer 215 may include an organic insulating material and an inorganic insulating material. In some embodiments, the first bank layer 215 may include a light blocking material and may be provided in black. The light blocking material may include carbon black, carbon nanotubes, a resin or paste including black dye, metal particles (e.g., nickel, aluminum, molybdenum, and any alloy thereof), metal oxide particles (e.g., chromium oxide), or metal nitride particles (e.g., chromium nitride). When the first bank layer 215 includes a light blocking material, the reflection of external light due to the metal structures disposed below the first bank layer 215 may be reduced.

The intermediate layer 212 may be disposed on the pixel electrode 211. The intermediate layer 212 may be disposed in the first opening of the bank layer 215. The intermediate layer 212 may include a low molecular weight material or a high molecular weight material and may emit red light, green light, blue light, or white light. In an embodiment, the intermediate layer 212 may include a layer patterned to correspond to each of the pixel electrodes 211. In some embodiments, the intermediate layer 212 may be integrally formed as a single body over the pixel electrodes 211.

In some embodiments, a hole injection layer (HIL) and/or a hole transport layer (HTL) may be disposed between the pixel electrode 211 and the intermediate layer 212.

The opposite electrode 213 may be disposed on the intermediate layer 212. The opposite electrode 213 may include a conductive material having a low work function. For example, the opposite electrode 213 may include a (semi)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or any alloy thereof. Alternatively, the opposite electrode 213 may further include a layer including ITO, IZO, ZnO, or In₂O₃ disposed on the (semi)transparent layer including the material described above. In an embodiment, the opposite electrode 213 may be disposed to completely cover the display area DA.

In some embodiments, an electron transport layer (ETL) and/or an electron injection layer (EIL) may be disposed between the intermediate layer 212 and the opposite electrode 213.

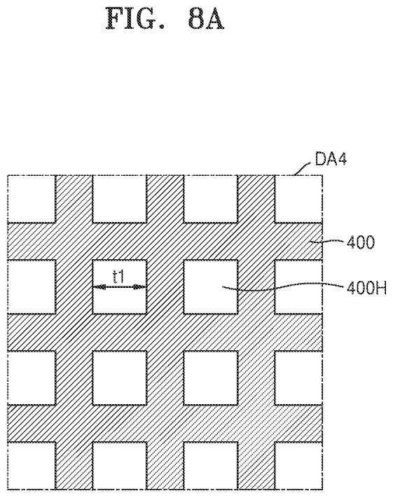

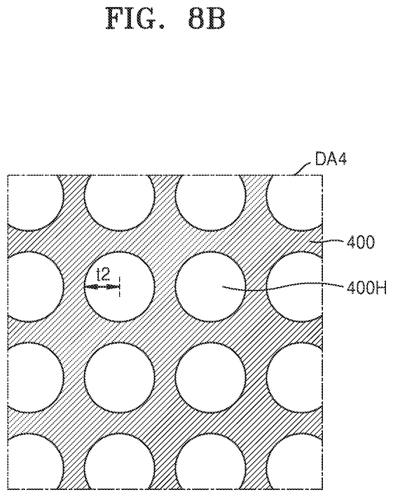

FIGS. 7A and 7B are cross-sectional views schematically illustrating a portion of a display apparatus, according to an embodiment. FIGS. 8A and 8B are schematic plan views of a conductive pattern layer according to an embodiment.

Referring to FIGS. 7A and 7B, the display panel DP may include a substrate 100, a pixel circuit layer PCL, and a display element layer DEL. The display element layer DEL may include a first display element DPE1. The substrate 100 may include a first display area DA1 and a third display area DA3 adjacent to the first display area DA1.

The pixel circuit layer PCL may be disposed on the substrate 100. The pixel circuit layer PCL may include a first sub-pixel circuit PC1, an inorganic insulating layer IIL, a connection wiring, a first organic insulating layer 121, a second organic insulating layer 122, a third organic insulating layer 123, and a fourth organic insulating layer 124. In an embodiment, the inorganic insulating layer IIL may include a buffer layer 111, a first gate insulating layer 112, a second gate insulating layer 113, a first inorganic insulating layer 115, a second inorganic insulating layer 117, and an interlayer insulating layer 119.

A plurality of first sub-pixel circuits PC1 configured to respectively drive a plurality of first display elements may be in the third display area DA3. In other words, the first sub-pixel circuits PC1 may not be in the first display area DA1. The first sub-pixel circuit PC1 may include a first thin-film transistor TFT1, a second thin-film transistor TFT2, and a storage capacitor Cst.

In an embodiment, the inorganic insulating layer IIL may have a groove Gv or a hole overlapping the first display area DA1. The groove Gv may have a shape in which a portion of the inorganic insulating layer IIL is removed. For example, the buffer layer 111, the first gate insulating layer 112, the second gate insulating layer 113, the first inorganic insulating layer 115, the second inorganic insulating layer 117, and the interlayer insulating layer 119 may each include an opening overlapping the first display area DA1. The openings of the buffer layer 111, the first gate insulating layer 112, the second gate insulating layer 113, the first inorganic insulating layer 115, the second inorganic insulating layer 117, and the interlayer insulating layer 119 may be formed through separate processes or may be formed simultaneously through the same process. When the openings of the buffer layer 111, the first gate insulating layer 112, the second gate insulating layer 113, the first inorganic insulating layer 115, the second inorganic insulating layer 117, and the interlayer insulating layer 119 are formed through separate processes, the groove Gv may have a stepped shape such as a stair shape.

The first organic insulating layer 121 may fill the groove Gv. For example, a portion of the first organic insulating layer 121 may at least partially fill the groove Gv. The first organic insulating layer 121 may have higher transmittance (e.g., light transmittance) than the inorganic insulating layer IIL. Accordingly, the transmittance of the first display area DA1 may increase.

FIGS. 7A and 7B illustrate that the inorganic insulating layer IIL has the groove Gv, but in another embodiment, the inorganic insulating layer IIL may not have the groove Gv. In this case, for example, the buffer layer 111, the first gate insulating layer 112, the second gate insulating layer 113, the first inorganic insulating layer 115, the second inorganic insulating layer 117, and the interlayer insulating layer 119 may be continuously arranged in the first display area DA1.

A plurality of connection wirings may be provided. The connection wirings may be electrically connected to the first sub-pixel circuits PC1, respectively. The connection wirings may electrically connect the first display elements DPE1 to the first sub-pixel circuits PC1, respectively.

In an embodiment, the connection wiring may include a first connection wiring CWL1 and a second connection wiring CWL2.

In an embodiment, the first connection wiring and the second connection wiring may each extend from the third display area DA3 to the first display area DA1. In other words, the first connection wiring and the second connection wiring may each extend from the third display area DA3 to the first display area DA1 through a fourth display area DA4 that is a boundary between the third display area Da3 and the first display area DA1. The first connection wiring and the second connection wiring may each include a transparent conducting oxide (TCO). The first connection wiring CWL1 and the second connection wiring CWL2 may each include, for example, a conductive oxide, such as ITO, IZO, ZnO, In₂O₃, IGO, or AZO.

In an embodiment, FIGS. 7A and 7B illustrate that the first connection wiring CWL1 and the second connection wiring CWL2 connected to the first display element DPE1 are on different layers. In an embodiment, the first connection wiring CWL1 may be between the second organic insulating layer 122 and the display element layer DEL. The second connection wiring CWL2 may be between the third organic insulating layer 123 and the display element layer DEL. Although not illustrated, a third connection wiring may be disposed on the fourth organic insulating layer 124. One end of the third connection wiring may cover the edge of the pixel electrode 211. In another embodiment, the first connection wiring CWL1 and the second connection wiring CWL2 may be on the same layer. However, a case where the first connection wiring CWL1 and the second connection wiring CWL2 may be on different layers is described below.

Referring to FIGS. 7A and 7B, at least one of the second organic insulating layer 122 and the third organic insulating layer 123 may have an opening. In an embodiment, the second organic insulating layer 122 may include an opening 122OP disposed in the first display area DA1.

Referring to FIG. 7A, the first connection wiring CWL1 may be disposed on the second organic insulating layer 122. Because the first connection wiring CWL1 extends from the third display area DA3 to the first display area DA1 through the fourth display area DA4, the first connection wiring CWL1 may be disposed on the groove Gv of the inorganic insulating layer IIL and the opening 122OP of the second organic insulating layer 122. The first connection wiring CWL1 may be disposed on the first organic insulating layer 121 in the opening 122OP of the second organic insulating layer 122.

The first connection wiring CWL1 may be electrically connected to the first sub-pixel circuit PC1 through a bridge wiring BWL disposed between the first organic insulating layer 121 and the second organic insulating layer 122. In an embodiment, the bridge wiring BWL may be electrically connected to the first sub-pixel circuit PC1 through a contact hole formed through the first organic insulating layer 121. The bridge wiring BWL may be electrically connected to the first connection wiring CWL1 through a contact hole formed through the second organic insulating layer 122.

In an embodiment, the second organic insulating layer 122, the third organic insulating layer 123, and the fourth organic insulating layer 124 may be disposed on the bridge wiring BWL. The first connection wiring CWL1 may be electrically connected to the first display element DPE1 through contact holes formed through the third organic insulating layer 123 and the fourth organic insulating layer 124. Therefore, the first display element DPE1 may be electrically connected to the first sub-pixel circuit PC1 and may be driven by the first sub-pixel circuit PC1.

Referring to FIG. 7B, the second connection wiring CWL2 may be between the third organic insulating layer 123 and the fourth organic insulating layer 124. In an embodiment, the second connection wiring CWL2 may be electrically connected to the first sub-pixel circuit PC1 through a bridge wiring BWL disposed between the first organic insulating layer 121 and the second organic insulating layer 122. In an embodiment, the bridge wiring BWL may be electrically connected to the first sub-pixel circuit PC1 through a contact hole formed through the first organic insulating layer 121. The second connection wiring CWL2 may be electrically connected to the bridge wiring BWL through contact holes formed through the second organic insulating layer 122 and the third organic insulating layer 123.

The fourth organic insulating layer 124 may be disposed on the second connection wiring CWL2. The second connection wiring CWL2 may be electrically connected to the first display element DPE1 through a contact hole formed through the fourth organic insulating layer 124. Therefore, the first display element DPE1 may be electrically connected to the first sub-pixel circuit PC1 and may be driven by the first sub-pixel circuit PC1.

In an embodiment, the bridge wiring BWL may include a material having good conductivity. The bridge wiring BWL may include a conductive material including molybdenum (Mo), aluminum (Al), copper (Cu), titanium (Ti), and the like, and may include a single layer or layers including the conductive material described above. The bridge wiring BWL may have a multilayer structure of Ti/Al/Ti.

In an embodiment, a conductive pattern layer 400 may be disposed between the connection wiring CWL1 and the first sub-pixel circuit PC1 on an organic insulating layer, for example, on the first organic insulating layer 121 in the fourth display area DA4 to overlap the connection wiring CWL1 in a plan view. In other words, the conductive pattern layer 400 may be disposed on the same layer as the bridge wiring BWL. However, the disclosure is not limited thereto. The conductive pattern layer 400 may include a plurality of holes 400H. The conductive pattern layer 400 may a floating pattern or may be connected to a constant voltage source.

The conductive pattern layer 400 may include the same material as the bridge wiring BWL. The conductive pattern layer 400 may include a material having good conductivity. The conductive pattern layer 400 may include a conductive material including molybdenum (Mo), aluminum (Al), copper (Cu), titanium (Ti), and the like, and may include a single layer or layers including the conductive material described above. The conductive pattern layer 400 may have a multilayer structure of Ti/Al/Ti.

At least one of the first source electrode (see SE1 of FIG. 6), the second source electrode (see SE2 of FIG. 6), the first drain electrode (see DE1 of FIG. 6), or the second drain electrode (see DE2 of FIG. 6), which is disposed on the interlayer insulating layer 119, may act as the data line (see DL of FIG. 3A) or the scan line (see SL of FIG. 3A) of the display apparatus DV. In other words, at least one of the first source electrode SE1, the second source electrode SE2, the first drain electrode DE1, and the second drain electrode DE2, which is disposed on the interlayer insulating layer 119, may be electrically connected to the data line DL or the scan line SL of the display apparatus DV or may be integrally formed as a single body. Alternatively, separately from the first source electrode SE1, the second source electrode SE2, the first drain electrode DE1, and the second drain electrode DE2, an electrode configured to provide a data signal or a scan signal may be disposed on the interlayer insulating layer 119. However, the disclosure is not limited thereto. The electrode configured to provide the data signal or the scan signal may be disposed on the second inorganic insulating layer 117 or the second gate insulating layer 113. Although not illustrated, in a plan view, the data line DL or the scan line SL of the display apparatus DV may be disposed to bypass the first display area DA1 without passing through the first display area DA1 in order to secure the light transmittance of the first display area DA1.

Data coupling may occur between at least one of the scan line SL and/or the data line DL which bypasses the first display area DA1 and is disposed on the interlayer insulating layer 119, and the first connection wiring CWL1 or the second connection wiring CWL2 disposed adjacent thereto. In other words, data coupling may occur between the electrode which is disposed on at least one of the inorganic insulating layers IIL and configured to transmit the data signal or the scan signal to the first sub-pixel circuit PC1, and the first connection wiring CWL1 and the second connection wiring CWL2 disposed adjacent thereto.

In order to prevent data coupling between the electrode configured to provide the data signal or the scan signal to the first sub-pixel circuit PC1 and the first connection wiring CWL1 or the second connection wiring CWL2, the conductive pattern layer 400 may be disposed on the first organic insulating layer 121 in the fourth display area DA4. Data coupling may be prevented by arranging the conductive pattern layer 400 between the electrode configured to provide the data signal or the scan signal to the first sub-pixel circuit PC1 and the first connection wiring CWL1 or the second connection wiring CWL2.

When the conductive pattern layer 400 is disposed on the first organic insulating layer 121 in the fourth display area DA4, the amount of gases emitted from the first organic insulating layer 121 may be restricted, and thus, the intermediate layer 212 may deteriorate. Due to the deterioration of the intermediate layer 212, the area of the emission area of the first display element DPE1 may be reduced, and thus the visibility of the display apparatus may be reduced.

Referring to FIGS. 8A and 8B, the conductive pattern layer 400 may include a plurality of holes 400H formed through the conductive pattern layer 400 in order to prevent data coupling between the electrode configured to provide the data signal or the scan signal to the first sub-pixel circuit PC1 and the first connection wiring CWL1 or the second connection wiring CWL2 while maintaining the amount of gases released from the first organic insulating layer 121 at an appropriate level. In order to simultaneously prevent the deterioration of the intermediate layer 212 and the data coupling, the proportion of the area occupied by the holes 400H among the area of the conductive pattern layer 400 (the area of the holes 400H included in the conductive pattern layer 400) may be about 30% to about 40%. The area of at least one of the holes 400H included in the conductive pattern layer 400 may be about 265 μm² to about 365 μm².

The holes 400H included in the conductive pattern layer 400 may have square shapes, rectangular shapes, or circular shapes. However, the disclosure is not limited thereto. The shape of the holes 400H included in the conductive pattern layer 400 may have a cross shape or an elliptical shape.

In an embodiment, when the holes 400H included in the conductive pattern layer 400 have square shapes, a length t1 of one side of the square may be about 16.3 μm to about 19.1 μm. When the holes 400H included in the conductive pattern layer 400 have rectangular shapes, the area of at least one of the holes 400H may be about 265 μm² to about 365 μm². In addition, when the holes 400H included in the conductive pattern layer 400 have circular shapes, a length t2 of the radius of the circle may be about 9.2 μm to about 10.78 μm.

Although FIGS. 8A and 8B illustrate that the holes 400H included in the conductive pattern layer 400 are arranged in a matrix configuration, the disclosure is not limited thereto. The holes 400H included in the conductive pattern layer 400 may be arranged oblique to each other.

FIGS. 7A and 7B illustrate that the first sub-pixel circuit PC1 corresponding to the first display element DPE1 is electrically connected through one connection wiring, but the disclosure is not limited thereto. For example, FIG. 6A illustrates that the first display element DPE1 is electrically connected to the first sub-pixel circuit PC1 through the first connection wiring CWL1 and the first connection wiring CWL1 is in direct contact with the pixel electrode 211 of the first display element DPE1, but in some embodiments, an intermediate layer may be further disposed between the first connection wiring CWL1 and the pixel electrode 211 of the first display element DPE1 on the same layer as at least one of the second connection wiring CWL2 and the third connection wiring CWL3.

The display element layer DEL may be disposed on the pixel circuit layer PCL. The display element layer DEL may include a first bank layer 215 and a first display element DPE1. The first display element DPE1 may be disposed on the fourth organic insulating layer 124.

The first bank layer 215 may include a first portion 215A overlapping a portion of the first display area DA1 (see a portion indicated by a dashed line in the first bank layer 215 of FIG. 7A). The first portion 215A may not overlap the pixel electrode 211. The first portion 215A may be a region spaced apart from a first opening of the first bank layer 215 exposing the pixel electrode 211. FIGS. 7A and 7B illustrate that the first bank layer 215 extends continuously while including the first portion 215A, but in some embodiments, the first bank layer 215 may have a second opening corresponding to the first portion 215A. In other words, the first portion 215A may be removed. When the first bank layer 215 has the second opening corresponding to the first portion 215A, the transmittance (e.g., light transmittance) of the display panel DP in the first display area DA1 may be improved. A region of the first display area DA1 overlapping the first portion 215A may correspond to the transmission area TA.

The first display element DPE1 may be electrically connected to the first sub-pixel circuit PC1. The first display element DPE1 may include a pixel electrode 211 and an opposite electrode 213. In an embodiment, the first display element DPE1 may include an intermediate layer 212 configured to emit red light, green light, or blue light.

The opposite electrode 213 may include a second portion 213A overlapping a portion of the first display area DA1 (see a portion indicated by a dashed line in the opposite electrode 213 in FIG. 7A). The second portion 213A may not overlap the pixel electrode 211. FIGS. 7A and 7B illustrate that the opposite electrode 213 extends continuously from the second portion 213A, but in some embodiments, the opposite electrode 213 may have an opening corresponding to the second portion 213A. In other words, the second portion 213A may be removed. When the opposite electrode 213 has the opening corresponding to the second portion 213A, the transmittance (e.g., light transmittance) of the display panel DP in the first display area DA1 may be improved. A region of the first display area DA1 overlapping the second portion 213A may correspond to the transmission area TA.

Data coupling may occur between at least one of the scan line SL and the data line DL which bypasses the first display area DA1 and is disposed on the interlayer insulating layer 119, and the first connection wiring CWL1 or the second connection wiring CWL2 disposed adjacent thereto. In order to prevent data coupling, a conductive pattern layer 400 may be disposed on the first organic insulating layer 121 in the fourth display area DA4. When the conductive pattern layer 400 is disposed, the amount of gases released from the first organic insulating layer 121 may be reduced, and thus, the intermediate layer 212 may deteriorate. Due to the deterioration of the intermediate layer 212, the area of the emission area of the first display element DPE1 may be reduced, and thus, the visibility of the display apparatus may be reduced.

In an embodiment, the conductive pattern layer 400 may include a plurality of holes 400H.

The proportion of the area occupied by the holes 400H among the area of the conductive pattern layer 400 (the area of the holes 400H included in the conductive pattern layer 400) may be about 30% to about 40%. Because the conductive pattern layer 400 includes the holes 400H having an appropriate area, the data coupling of the display apparatus DV and the deterioration of the intermediate layer 212 may be prevented.

According to one or more embodiments, a display panel with improved reliability and visibility and a display apparatus including the same may be implemented. The scope of the disclosure is not limited by such an effect.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display panel comprising:
a substrate comprising a first area, a second area at least partially surrounding the first area, and a third area between the first area and the second area;
a first pixel circuit arranged in the third area and comprising a first transistor, a storage capacitor, and a second transistor, wherein the first transistor comprises a first semiconductor layer and a first gate electrode, and the second transistor comprises a second semiconductor layer and a second gate electrode;
a first organic insulating layer disposed on the first transistor and the second transistor;
a second organic insulating layer disposed on the first organic insulating layer;
a first light-emitting diode arranged in the first area and electrically connected to the first pixel circuit, the first light-emitting diode comprising a first electrode disposed on the second organic insulating layer; and
a conductive pattern layer disposed on the first organic insulating layer in a fourth area that is a boundary between the first area and the second area, the conductive pattern layer comprising a plurality of holes.

2. The display panel of claim 1, wherein an area occupied by the plurality of holes among an area of the conductive pattern layer is from about 30% to about 40%.

3. The display panel of claim 1, wherein an area of at least one of the plurality of holes in the conductive pattern layer is from about 265 μm² to about 365 μm².

4. The display panel of claim 3, wherein each of the plurality of holes in the conductive pattern layer has a rectangular shape.

5. The display panel of claim 4, wherein each of the plurality of holes in the conductive pattern layer has a square shape.

6. The display panel of claim 5, wherein a length of one side of the each of the plurality of holes in the conductive pattern layer is from about 16.3 μm to about 19.1 μm.

7. The display panel of claim 3, wherein each of the plurality of holes in the conductive pattern layer has a circular shape.

8. The display panel of claim 7, wherein a radius of at least one of the each of the plurality of holes in the conductive pattern layer is from about 9.2 μm to about 10.78 μm.

9. The display panel of claim 1, further comprising:
a third organic insulating layer disposed between the first organic insulating layer and the second organic insulating layer; and
a first connection wiring disposed on the third organic insulating layer.

10. The display panel of claim 9, further comprising:
a fourth organic insulating layer disposed between the second organic insulating layer and the third organic insulating layer; and
a second connection wiring disposed on the fourth organic insulating layer.

11. The display panel of claim 1, wherein the first light-emitting diode further comprises:
a first intermediate layer disposed on the first electrode; and
a first opposite electrode disposed on the first intermediate layer.

12. The display panel of claim 1, further comprising:
a second pixel circuit arranged in the second area; and
a second light-emitting diode arranged in the second area and electrically connected to the second pixel circuit.

13. The display panel of claim 1, further comprising:
a third pixel circuit arranged in the third area; and
a third light-emitting diode arranged in the third area and electrically connected to the third pixel circuit.

14. The display panel of claim 1, wherein the first area comprises a transmission area.

15. The display panel of claim 14, wherein the first light-emitting diode and the transmission area are alternately arranged in the first area.

16. A display apparatus comprising:
a display panel comprising a first area, a second area at least partially surrounding the first area, and a third area between the first area and the second area; and
a component disposed on a lower surface of the display panel and overlapping at least a portion of the first area,
wherein the display panel further comprises:
a first pixel circuit arranged in the third area and comprising a first transistor, a storage capacitor, and a second transistor, wherein the first transistor comprises a first semiconductor layer and a first gate electrode, and the second transistor comprises a second semiconductor layer and a second gate electrode;
a first organic insulating layer disposed on the first transistor and the second transistor;
a second organic insulating layer disposed on the first organic insulating layer;
a first light-emitting diode arranged in the first area and electrically connected to the first pixel circuit, the first light-emitting diode comprising a first electrode disposed on the second organic insulating layer; and
a conductive pattern layer disposed on the first organic insulating layer in a fourth area that is a boundary between the first area and the second area, the conductive pattern layer comprising a plurality of holes.

17. The display apparatus of claim 16, wherein an area occupied by the plurality of holes among an area of the conductive pattern layer is from about 30% to about 40%.

18. The display apparatus of claim 16, wherein an area of at least one of the plurality of holes in the conductive pattern layer is from about 265 μm² to about 365 μm².

19. The display apparatus of claim 16, wherein each of the plurality of holes in the conductive pattern layer has a square shape.

20. The display apparatus of claim 19, wherein a length of one side of the each of the plurality of holes in the conductive pattern layer is from about 16.3 μm to about 19.1 μm.
